(19) United States
(12) Patent Application Publication
(10) Pub. No.: US 2026/0101069 A1
(43) Pub. Date: Apr. 9, 2026

(54) METHODS AND APPARATUSES FOR ENCODING AND DECODING AN IMAGE OR A VIDEO

(71) Applicant: InterDigital CE Patent Holdings, SAS, Paris (FR)

(72) Inventors: Federico Lo Bianco, Rennes (FR); Franck Galpin, Thorigne-Fouillard (FR); Mikael Le Pendu, Rennes (FR); João Miguel Pereira da Silva Santos, Rennes (FR)

(21) Appl. No.: 19/120,398

(22) PCT Filed: Oct. 3, 2023
(86) PCT No.: PCT/EP2023/077334

§ 371 Date: Apr. 11, 2025

(30) Foreign Application Priority Data
Oct. 11, 2022 (EP) 22306525.1
Dec. 19, 2022 (EP) 22306937.8

(51) Int. Cl. H04N 19/91; H04N 19/184

(52) U.S. Cl. CPC H04N 19/91; H04N 19/184

(57) ABSTRACT

A method and an apparatus for encoding or decoding a video. An initial value for at least one parameter of a context of an entropy coder is determined. The context is associated to at least one binary symbol of a sequence of binary symbols to entropy code. The initial value is determined based on a bitrate determination for entropy encoding a set of binary symbols or based on decoding of an information representative of the initial value. The at least one parameter is initialized using the determined the initial value, and the sequence of binary symbols is entropy encoded or decoded based on the at least one parameter initialized.

This application claims the priority to European Applications No. 22306525.1, filed on 11 Oct. 2022 and No 22306937.8, filed on 19 Dec. 2022, which are incorporated herein by reference in their entirety.

### TECHNICAL FIELD

The present embodiments generally relate to video compression. The present embodiments relate to a method and an apparatus for encoding or decoding an image or a video. More particularly, the present embodiments relate to improving entropy coding and decoding.

### BACKGROUND

To achieve high compression efficiency, image and video coding schemes usually employ prediction and transform to leverage spatial and temporal redundancy in the video content. Generally, intra or inter prediction is used to exploit the intra or inter picture correlation, then the differences between the original block and the predicted block, often denoted as prediction errors or prediction residuals, are transformed, quantized, and entropy coded. To reconstruct the video, the compressed data are decoded by inverse processes corresponding to the entropy coding, quantization, transform, and prediction.

### SUMMARY

According to an aspect, a method for encoding an image or a video is provided. The method comprises determining an initial value for at least one parameter of a context of an entropy coder, the context being associated to at least one binary symbol of a sequence of binary symbols representative of an image or a video, wherein determining the initial value is based on a bitrate determination for entropy encoding a set of binary symbols associated to the context, initializing the at least one parameter to the initial value, entropy encoding the at least one binary symbol based on the at least one parameter initialized.

According to another aspect, an apparatus for encoding an image or a video is provided. The apparatus comprises one or more processors operable to determine an initial value for at least one parameter of a context of an entropy coder, the context being associated to at least one binary symbol of a sequence of binary symbols representative of an image or a video, wherein determining the initial value is based on a bitrate determination for entropy encoding a set of binary symbols associated to the context, initialize the at least one parameter to the initial value, entropy encode the at least one binary symbol based on the at least one parameter initialized.

According to another aspect, a method for decoding an image or a video is provided. In an embodiment, the method comprises determining at least one initial value for at least one parameter of a context of an entropy coder, the context being associated to at least one binary symbol of a sequence of binary symbols representative of an image or a video, wherein determining the at least one initial value is based on a bitrate determination for entropy encoding a set of binary symbols associated to the context, initializing the at least one parameter to the determined initial value, entropy decoding the sequence of binary symbols based on the at least one parameter initialized.

In another embodiment, the method comprises determining at least one initial value for at least one parameter of a context of an entropy coder, the context being associated to at least one binary symbol of a sequence of binary symbols representative of an image or a video, wherein determining the at least one initial value is based on decoding an information representative of the at least one initial value, initializing the at least one parameter to the determined initial value, entropy decoding the sequence of binary symbols based on the at least one parameter initialized.

According to another aspect, an apparatus for decoding an image or a video is provided.

In an embodiment, the apparatus comprises one or more processors operable to determine at least one initial value for at least one parameter of a context of an entropy coder, the context being associated to at least one binary symbol of a sequence of binary symbols representative of an image or a video, wherein determining the at least one initial value is based on a bitrate determination for entropy encoding a set of binary symbols associated to the context, initialize the at least one parameter to the determined initial value, entropy decode the sequence of binary symbols based on the at least one parameter initialized.

In another embodiment, the apparatus comprises one or more processors operable to determine at least one initial value for at least one parameter of a context of an entropy coder, the context being associated to at least one binary symbol of a sequence of binary symbols representative of an image or a video, wherein determining the at least one initial value is based on decoding an information representative of the at least one initial value, initialize the at least one parameter to the determined initial value, entropy decode the sequence of binary symbols based on the at least one parameter initialized.

In some embodiments, the at least one parameter comprises at least one of: a probability value, a size of a window used for updating the probability value after encoding or decoding a binary symbol, a weight used in a weighted average for determining a probability value for encoding or decoding a binary symbol.

Further embodiments that can be used alone or in combination are described herein.

One or more embodiments also provide a computer program comprising instructions which when executed by one or more processors cause the one or more processors to perform the method for encoding/decoding an image or a video according to any of the embodiments described herein. One or more of the present embodiments also provide a non-transitory computer readable medium and/or a computer readable storage medium having stored thereon instructions for encoding/decoding an image or a video according to the methods described herein.

One or more embodiments also provide a computer readable storage medium having stored thereon a bitstream generated according to the methods described herein. One or more embodiments also provide a method and apparatus for transmitting or receiving the bitstream generated according to the methods described above.

### BRIEF DESCRIPTION OF THE DRAWINGS

FIG. 1 illustrates a block diagram of a system within which aspects of the present embodiments may be implemented.

FIG. 2 illustrates a block diagram of an embodiment of a video encoder within which aspects of the present embodiments may be implemented.

FIG. 3 illustrates a block diagram of an embodiment of a video decoder within which aspects of the present embodiments may be implemented.

FIG. 4 illustrates an example of a CABAC encoding scheme.

FIG. 5 illustrates an example of CABAC parameters initialization.

FIG. 6 illustrates an example of a flowchart for decoding a single binary decision in VVC.

FIG. 7 illustrates an example of a method for encoding an image or a video according to an embodiment.

FIG. 8 illustrates an example of a method for decoding an image or a video according to an embodiment.

FIG. 9 illustrates an example of a method for encoding an image or a video according to an embodiment.

FIG. 10 illustrates an example of a method for decoding an image or a video according to an embodiment.

FIG. 11 illustrates an example of a method for encoding an image or a video according to an embodiment.

FIG. 12 illustrates an example of a method for encoding an image or a video according to an embodiment.

FIG. 13 illustrates a block diagram of a system within which aspects of the present embodiments may be implemented, according to another embodiment.

FIG. 14 shows two remote devices communicating over a communication network in accordance with an example of the present principles.

FIG. 15 shows the syntax of a signal in accordance with an example of the present principles.

FIG. 16A illustrates an example of a method for encoding and of a method for decoding an image or a video according to an embodiment.

FIG. 16B illustrates an example of a method for encoding and of a method for decoding an image or a video according to another embodiment.

FIG. 17 illustrates an example of a method for encoding and of a method for decoding an image or a video according to another embodiment.

FIG. 18 illustrates an example of a method for encoding and of a method for decoding an image or a video according to another embodiment.

FIG. 19 illustrates an example of a method for encoding and of a method for decoding an image or a video according to another embodiment.

### DETAILED DESCRIPTION

This application describes a variety of aspects, including tools, features, embodiments, models, approaches, etc. Many of these aspects are described with specificity and, at least to show the individual characteristics, are often described in a manner that may sound limiting. However, this is for purposes of clarity in description, and does not limit the application or scope of those aspects. Indeed, all of the different aspects can be combined and interchanged to provide further aspects. Moreover, the aspects can be combined and interchanged with aspects described in earlier filings as well.

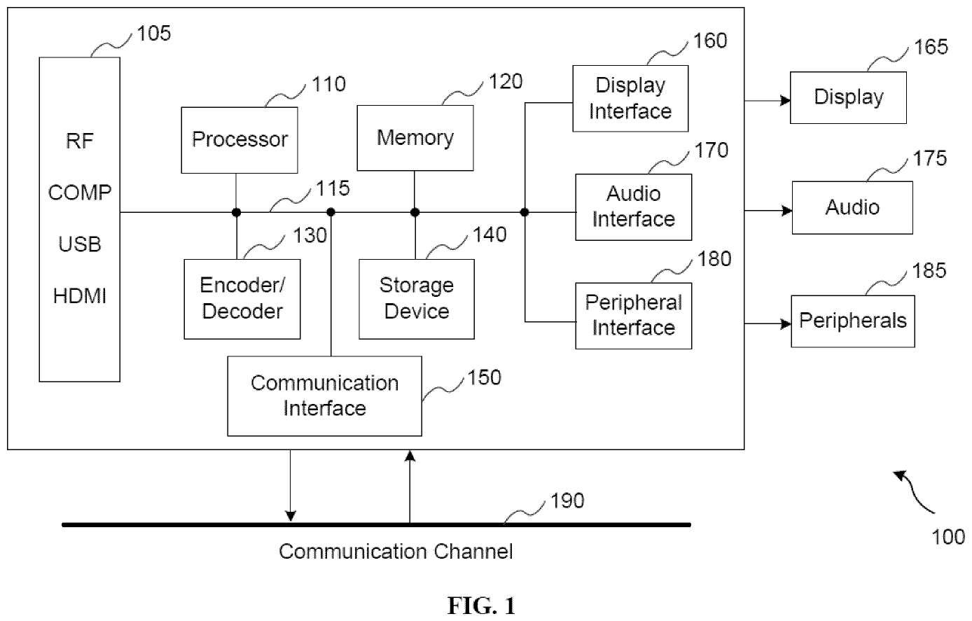

The aspects described and contemplated in this application can be implemented in many different forms. FIGS. 1, 2 and 3 below provide some embodiments, but other embodiments are contemplated and the discussion of FIGS. 1, 2 and 3 does not limit the breadth of the implementations. At least one of the aspects generally relates to video encoding and decoding, and at least one other aspect generally relates to transmitting a bitstream generated or encoded. These and other aspects can be implemented as a method, an apparatus, a computer readable storage medium having stored thereon instructions for encoding or decoding video data according to any of the methods described, and/or a computer readable storage medium having stored thereon a bitstream generated according to any of the methods described.

In the present application, the terms “reconstructed” and “decoded” may be used interchangeably, the terms “pixel” and “sample” may be used interchangeably, the terms “image,” “picture” and “frame” may be used interchangeably.

Various methods are described herein, and each of the methods comprises one or more steps or actions for achieving the described method. Unless a specific order of steps or actions is required for proper operation of the method, the order and/or use of specific steps and/or actions may be modified or combined. Additionally, terms such as “first”, “second”, etc. may be used in various embodiments to modify an element, component, step, operation, etc., such as, for example, a “first decoding” and a “second decoding”. Use of such terms does not imply an ordering to the modified operations unless specifically required. So, in this example, the first decoding need not be performed before the second decoding, and may occur, for example, before, during, or in an overlapping time period with the second decoding.

The present aspects are not limited to VVC or HEVC, and can be applied, for example, to other standards and recommendations, whether pre-existing or future-developed, and extensions of any such standards and recommendations (including VVC and HEVC). Unless indicated otherwise, or technically precluded, the aspects described in this application can be used individually or in combination.

FIG. 1 illustrates a block diagram of an example of a system in which various aspects and embodiments can be implemented. System 100 may be embodied as a device including the various components described below and is configured to perform one or more of the aspects described in this application. Examples of such devices, include, but are not limited to, various electronic devices such as personal computers, laptop computers, smartphones, tablet computers, digital multimedia set top boxes, digital television receivers, personal video recording systems, connected home appliances, and servers. Elements of system 100, singly or in combination, may be embodied in a single integrated circuit, multiple ICs, and/or discrete components. For example, in at least one embodiment, the processing and encoder/decoder elements of system 100 are distributed across multiple ICs and/or discrete components. In various embodiments, the system 100 is communicatively coupled to other systems, or to other electronic devices, via, for example, a communications bus or through dedicated input and/or output ports. In various embodiments, the system 100 is configured to implement one or more of the aspects described in this application.

The system 100 includes at least one processor 110 configured to execute instructions loaded therein for implementing, for example, the various aspects described in this application. Processor 110 may include embedded memory, input output interface, and various other circuitries as known in the art. The system 100 includes at least one memory 120 (e.g., a 35 volatile memory device, and/or a non-volatile memory device). System 100 includes a storage device 140, which may include non-volatile memory and/or volatile memory, including, but not limited to, EEPROM, ROM, PROM, RAM, DRAM, SRAM, flash, magnetic disk drive, and/or optical disk drive. The storage device 140 may include an internal storage device, an attached storage device, and/or a network accessible storage device, as non-limiting examples.

System 100 includes an encoder/decoder module 130 configured, for example, to process data to provide an encoded video or decoded video, and the encoder/decoder module 130 may include its own processor and memory. The encoder/decoder module 130 represents module(s) that may be included in a device to perform the encoding and/or decoding functions. As is known, a device may include one or both of the encoding and decoding modules. Additionally, encoder/decoder module 130 may be implemented as a separate element of system 100 or may be incorporated within processor 110 as a combination of hardware and software as known to those skilled in the art.

Program code to be loaded onto processor 110 or encoder/decoder 130 to perform the various aspects described in this application may be stored in storage device 140 and subsequently loaded onto memory 120 for execution by processor 110. In accordance with various embodiments, one or more of processor 110, memory 120, storage device 140, and encoder/decoder module 130 may store one or more of various items during the performance of the processes described in this application. Such stored items may include, but are not limited to, the input video, the decoded video or portions of the decoded video, the bitstream, matrices, variables, and intermediate or final results from the processing of equations, formulas, operations, and operational logic.

In some embodiments, memory inside of the processor 110 and/or the encoder/decoder module 130 is used to store instructions and to provide working memory for processing that is needed during encoding or decoding. In other embodiments, however, a memory external to the processing device (for example, the processing device may be either the processor 110 or the encoder/decoder module 130) is used for one or more of these functions. The external memory may be the memory 120 and/or the storage device 140, for example, a dynamic volatile memory and/or a non-volatile flash memory. In several embodiments, an external non-volatile flash memory is used to store the operating system of a television. In at least one embodiment, a fast external dynamic volatile memory such as a RAM is used as working memory for video coding and decoding operations, such as for MPEG-2, (MPEG refers to the Moving Picture Experts Group, MPEG-2 is also referred to as ISO/IEC 13818, and 13818-1 is also known as H.222, and 13818-2 is also known as H.262), HEVC (HEVC refers to High Efficiency Video Coding, also known as H.265 and MPEG-H Part 2), or VVC (Versatile Video Coding, a new standard being developed by JVET, the Joint Video Experts Team).

The input to the elements of system 100 may be provided through various input devices as indicated in block 105. Such input devices include, but are not limited to, (i) a radio frequency (RF) portion that receives an RF signal transmitted, for example, over the air by a broadcaster, (ii) a Component (COMP) input terminal (or a set of COMP input terminals), (iii) a Universal Serial Bus (USB) input terminal, and/or (iv) a High Definition Multimedia Interface (HDMI) input terminal. Other examples, not shown in FIG. 1, include composite video.

In various embodiments, the input devices of block 105 have associated respective input processing elements as known in the art. For example, the RF portion may be associated with elements suitable for (i) selecting a desired frequency (also referred to as selecting a signal, or band-limiting a signal to a band of frequencies), (ii) down converting the selected signal, (iii) band-limiting again to a narrower band of frequencies to select (for example) a signal frequency band which can be referred to as a channel in certain embodiments, (iv) demodulating the down converted and band-limited signal, (v) performing error correction, and (vi) demultiplexing to select the desired stream of data packets. The RF portion of various embodiments includes one or more elements to perform these functions, for example, frequency selectors, signal selectors, band-limiters, channel selectors, filters, downconverters, demodulators, error correctors, and demultiplexers. The RF portion may include a tuner that performs various of these functions, including, for example, down converting the received signal to a lower frequency (for example, an intermediate frequency or a near-baseband frequency) or to baseband. In one set-top box embodiment, the RF portion and its associated input processing element receives an RF signal transmitted over a wired (for example, cable) medium, and performs frequency selection by filtering, down converting, and filtering again to a desired frequency band. Various embodiments rearrange the order of the above-described (and other) elements, remove some of these elements, and/or add other elements performing similar or different functions. Adding elements may include inserting elements in between existing elements, for example, inserting amplifiers and an analog-to-digital converter. In various embodiments, the RF portion includes an antenna.

Additionally, the USB and/or HDMI terminals may include respective interface processors for connecting system 100 to other electronic devices across USB and/or HDMI connections. It is to be understood that various aspects of input processing, for example, Reed-Solomon error correction, may be implemented, for example, within a separate input processing IC or within processor 110 as necessary. Similarly, aspects of USB or HDMI interface processing may be implemented within separate interface ICs or within processor 110 as necessary. The demodulated, error corrected, and demultiplexed stream is provided to various processing elements, including, for example, processor 110, and encoder/decoder 130 operating in combination with the memory and storage elements to process the data stream as necessary for presentation on an output device.

Various elements of system 100 may be provided within an integrated housing, Within the integrated housing, the various elements may be interconnected and transmit data therebetween using suitable connection arrangement 115, for example, an internal bus as known in the art, including the I2C bus, wiring, and printed circuit boards.

The system 100 includes communication interface 150 that enables communication with other devices via communication channel 190. The communication interface 150 may include, but is not limited to, a transceiver configured to transmit and to receive data over communication channel 190. The communication interface 150 may include, but is not limited to, a modem or network card and the communication channel 190 may be implemented, for example, within a wired and/or a wireless medium.

Data is streamed to the system 100, in various embodiments, using a Wi-Fi network such as IEEE 802.11 (IEEE refers to the Institute of Electrical and Electronics Engineers). The Wi-Fi signal of these embodiments is received over the communications channel 190 and the communications interface 150 which are adapted for Wi-Fi communications. The communications channel 190 of these embodiments is typically connected to an access point or router that provides access to outside networks including the Internet for allowing streaming applications and other over-the-top communications. Other embodiments provide streamed data to the system 100 using a set-top box that delivers the data over the HDMI connection of the input block 105. Still other embodiments provide streamed data to the system 100 using the RF connection of the input block 105. As indicated above, various embodiments provide data in a non-streaming manner. Additionally, various embodiments use wireless networks other than Wi-Fi, for example a cellular network or a Bluetooth network.

The system 100 may provide an output signal to various output devices, including a display 165, speakers 175, and other peripheral devices 185. The display 165 of various embodiments includes one or more of, for example, a touchscreen display, an organic light-emitting diode (OLED) display, a curved display, and/or a foldable display. The display 165 can be for a television, a tablet, a laptop, a cell phone (mobile phone), or other device. The display 165 can also be integrated with other components (for example, as in a smart phone), or separate (for example, an external monitor for a laptop). The other peripheral devices 185 include, in various examples of embodiments, one or more of a stand-alone digital video disc (or digital versatile disc) (DVR, for both terms), a disk player, a stereo system, and/or a lighting system. Various embodiments use one or more peripheral devices 185 that provide a function based on the output of the system 100. For example, a disk player performs the function of playing the output of the system 100.

In various embodiments, control signals are communicated between the system 100 and the display 165, speakers 175, or other peripheral devices 185 using signaling such as AV.Link, CEC, or other communications protocols that enable device-to-device control with or without user intervention. The output devices may be communicatively coupled to system 100 via dedicated connections through respective interfaces 160, 170, and 180. Alternatively, the output devices may be connected to system 100 using the communications channel 190 via the communications interface 150. The display 165 and speakers 175 may be integrated in a single unit with the other components of system 100 in an electronic device, for example, a television. In various embodiments, the display interface 160 includes a display driver, for example, a timing controller (T Con) chip.

The display 165 and speaker 175 may alternatively be separate from one or more of the other components, for example, if the RF portion of input 105 is part of a separate set-top box. In various embodiments in which the display 165 and speakers 175 are external components, the output signal may be provided via dedicated output connections, including, for example, HDMI ports, USB ports, or COMP outputs.

The embodiments can be carried out by computer software implemented by the processor 110 or by hardware, or by a combination of hardware and software. As a non-limiting example, the embodiments can be implemented by one or more integrated circuits. The memory 120 can be of any type appropriate to the technical environment and can be implemented using any appropriate data storage technology, such as optical memory devices, magnetic memory devices, semiconductor-based memory devices, fixed memory, and removable memory, as non-limiting examples. The processor 110 can be of any type appropriate to the technical environment, and can encompass one or more of microprocessors, general purpose computers, special purpose computers, and processors based on a multi-core architecture, as non-limiting examples.

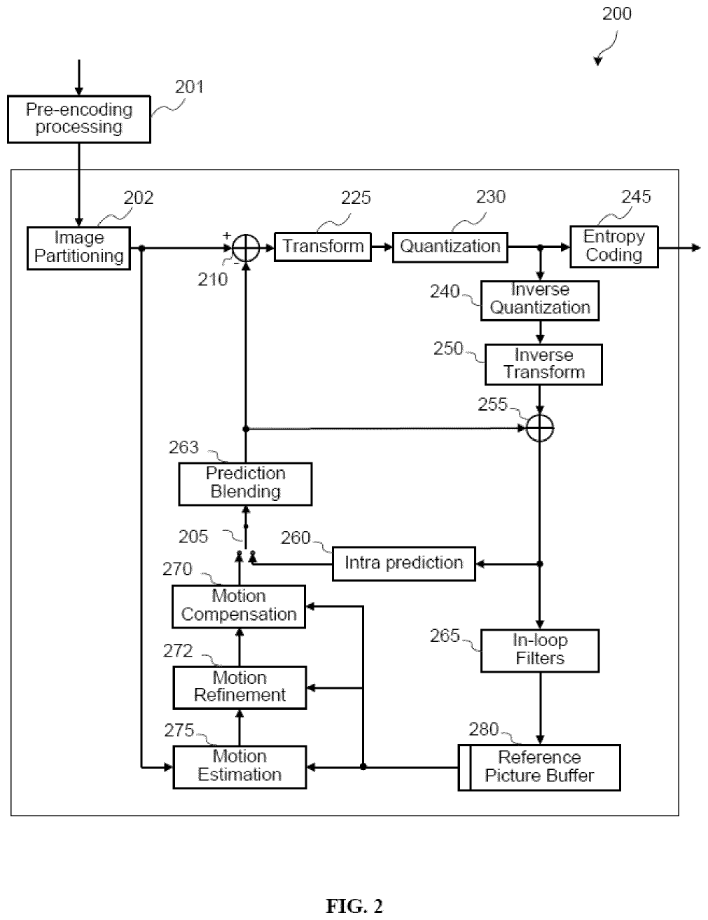

FIG. 2 illustrates an encoder 200. Variations of this encoder 200 are contemplated, but the encoder 200 is described below for purposes of clarity without describing all expected variations.

In some embodiments, FIG. 2 also illustrate an encoder in which improvements are made to the HEVC standard or a VVC standard or an encoder employing technologies similar to HEVC or VVC, such as an encoder ECM under development by JVET (Joint Video Exploration Team).

Before being encoded, the video sequence may go through pre-encoding processing (201), for example, applying a color transform to the input color picture (e.g., conversion from RGB 4:4:4 to YCbCr 4:2:0), or performing a remapping of the input picture components in order to get a signal distribution more resilient to compression (for instance using a histogram equalization of color components), or re-sizing the picture (ex: down-scaling). Metadata can be associated with the pre-processing, and attached to the bitstream.

In the encoder 200, a picture is encoded by the encoder elements as described below. The picture to be encoded is partitioned (202) and processed in units of, for example, CUs (Coding units) or blocks. In the disclosure, different expressions may be used to refer to such a unit or block resulting from a partitioning of the picture. Such wording may be coding unit or CU, coding block or CB, luminance CB, or block . . . . A CTU (Coding Tree Unit) may refer to a group of blocks or group of units. In some embodiments, a CTU may be considered as a block, or a unit as itself.

Each unit is encoded using, for example, either an intra or inter mode. When a unit is encoded in an intra mode, it performs intra prediction (260). In an inter mode, motion estimation (275) and compensation (270) are performed. The encoder decides (205) which one of the intra mode or inter mode to use for encoding the unit, and indicates the intra/inter decision by, for example, a prediction mode flag. The encoder may also blend (263) intra prediction result and inter prediction result, or blend results from different intra/inter prediction methods. Prediction residuals are calculated, for example, by subtracting (210) the predicted block from the original image block.

The motion refinement module (272) uses already available reference picture in order to refine the motion field of a block without reference to the original block. A motion field for a region can be considered as a collection of motion vectors for all pixels with the region. If the motion vectors are sub-block-based, the motion field can also be represented as the collection of all sub-block motion vectors in the region (all pixels within a sub-block has the same motion vector, and the motion vectors may vary from sub-block to sub-block). If a single motion vector is used for the region, the motion field for the region can also be represented by the single motion vector (same motion vectors for all pixels in the region).

The prediction residuals are then transformed (225) and quantized (230). The quantized transform coefficients, as well as motion vectors and other syntax elements, are entropy coded (245) to output a bitstream. The encoder can skip the transform and apply quantization directly to the non-transformed residual signal. The encoder can bypass both transform and quantization, i.e., the residual is coded directly without the application of the transform or quantization processes.

The encoder decodes an encoded block to provide a reference for further predictions. The quantized transform coefficients are de-quantized (240) and inverse transformed (250) to decode prediction residuals. Combining (255) the decoded prediction residuals and the predicted block, an image block is reconstructed. In-loop filters (265) are applied to the reconstructed picture to perform, for example, deblocking/SAO (Sample Adaptive Offset) filtering to reduce encoding artifacts. The filtered image is stored at a reference picture buffer (280).

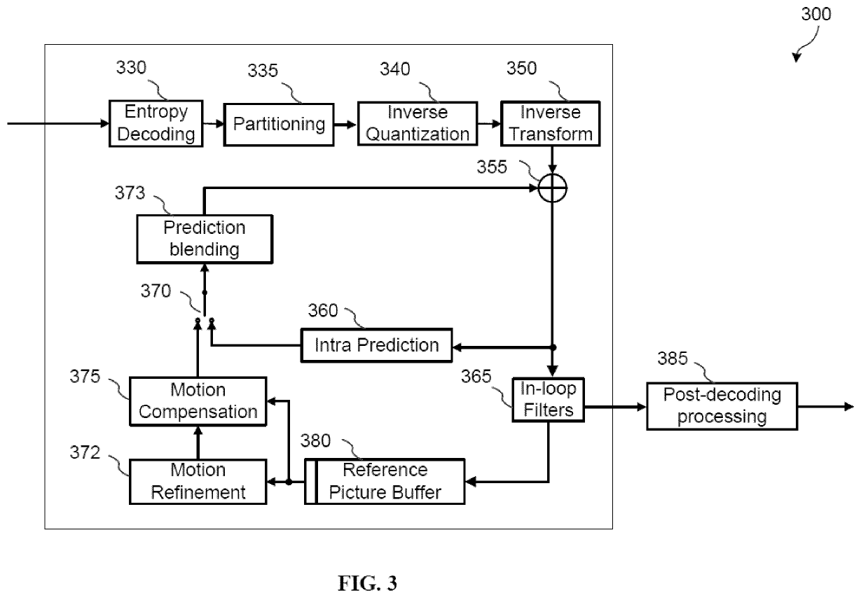

FIG. 3 illustrates a block diagram of a video decoder 300. In the decoder 300, a bitstream is decoded by the decoder elements as described below. Video decoder 300 generally performs a decoding pass reciprocal to the encoding pass as described in FIG. 2. The encoder 200 also generally performs video decoding as part of encoding video data.

In particular, the input of the decoder includes a video bitstream, which can be generated by video encoder 200. The bitstream is first entropy decoded (330) to obtain transform coefficients, motion vectors, and other coded information. The picture partition information indicates how the picture is partitioned. The decoder may therefore divide (335) the picture according to the decoded picture partitioning information. The transform coefficients are de-quantized (340) and inverse transformed (350) to decode the prediction residuals. Combining (355) the decoded prediction residuals and the predicted block, an image block is reconstructed.

The predicted block can be obtained (370) from intra prediction (360) or motion-compensated prediction (i.e., inter prediction) (375). The decoder may blend (373) the intra prediction result and inter prediction result, or blend results from multiple intra/inter prediction methods. Before motion compensation, the motion field may be refined (372) by using already available reference pictures. In-loop filters (365) are applied to the reconstructed image. The filtered image is stored at a reference picture buffer (380).

The decoded picture can further go through post-decoding processing (385), for example, an inverse color transform (e.g. conversion from YCbCr 4:2:0 to RGB 4:4:4) or an inverse remapping performing the inverse of the remapping process performed in the pre-encoding processing (201), or re-sizing the reconstructed pictures (ex: up-scaling). The post-decoding processing can use metadata derived in the pre-encoding processing and signaled in the bitstream.

Some of the embodiments described herein relates to context-based entropy encoding and context-based entropy decoding.

Any one of the embodiments described herein can be implemented for instance in an entropy encoding module 245 of the image or video encoder 200 or an entropy decoding module 330 of the image or video decoder 300.

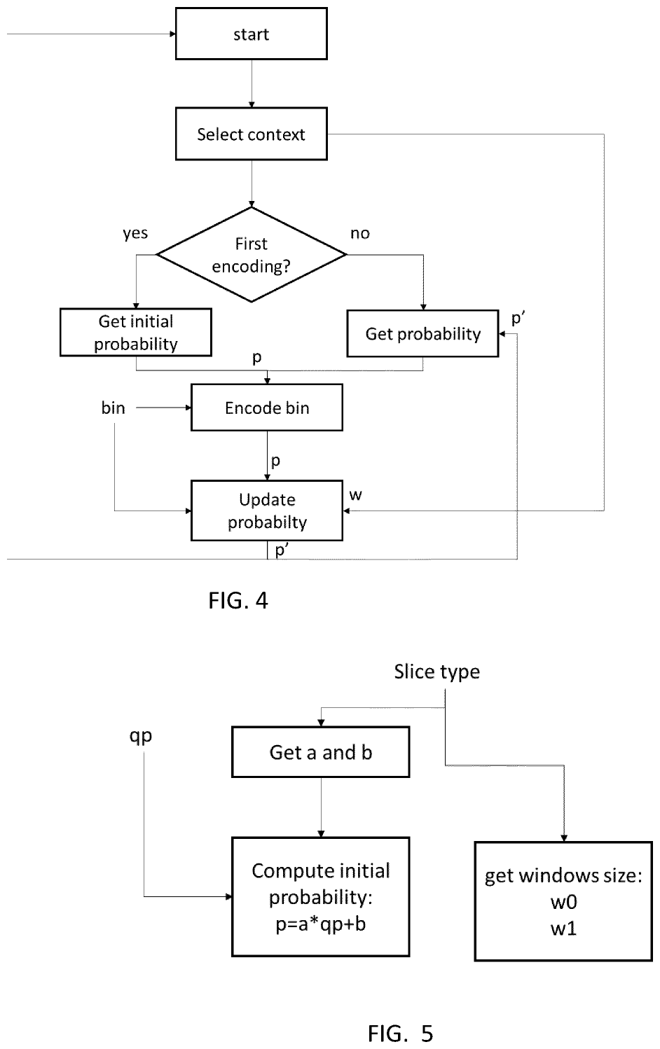

In current video codecs, a large part of the signaling is done using an entropy coding of the values to transmit to a decoder. Especially, using context adaptive binary arithmetic coding, such as CABAC, only binary values are encoded and generic values (other than binary value) should first undergo a binarization process. In context-based entropy coding, for each individual bin (or binary symbol) to encode/decode, a context is attached to the bin. One or more probability is/are associated to the context, wherein the probability indicates a probability that the bin is equal to a given binary value. Depending on the coder implementation, the given binary value can be a most probable binary value of the bin or a least probable binary value. The probability of the context attached to each bin to encode/decode is updated after each encoding/decoding of a bin associated to the same context. The speed at which the probability is updated is a parameter of the model. Another parameter is the initial probability used by the model (i.e. the probability used for encoding/decoding the first bin attached to that context). An example of an entropy coding is summed up in FIG. 4:
For each bin, a context associated to the bin is selected. Each context contains the following information:
   A current probability. In recent codecs such as VVC for example, 2 probabilities are maintained p0 and p1.
   The windows size(s), corresponding to the update speed of the probability. Typically, the probability is updated following: p′=w*b+ (1−w)*p, where p is the probability used for encoding a bin b, p′ the updated probability that is used for encoding a next bin (associated to the same context), b the current bin encoded/decoded using the probability p and w the window size. In recent codec, 2 probabilities are updated, using 2 different window sizes, w0 and w1. Each bin is then encoded/decoded by considering the mean of the two probabilities p0 and p1.
   The initial value of the probability. Typically, p0 and p1 are initialized using the same initial probability.

The parameters for a given context (initial probability, windows sizes) depend on external parameters, such as:
The type of slice to encode intra, biprediction, uni-direction (I, B or P)
The quantization parameter qp
Each context uses fixed (i.e. between encoder and decoder) parameters, and these parameters are decided per context.

At the beginning of each slice, the parameters are initialized as depicted in FIG. 5. Moreover, a flag called sh_cabac_init_flag is signaled in the slice header for non intra slice which allows to switch the parameters to use for initialization: when the flag is true for a B slice, P slice parameters set are used for initialization, while when the flag is false, B slice parameters are used. A similar mechanism is in place for the P slice.

| | |
|---|---|
| if( sh_slice_type != I ) { | |
| if( pps_cabac_init_present_flag ) | |
| sh_cabac_init_flag | u(1) |

In the VVC, CABAC entropy coding contains the following major changes compared to the CABAC design in HEVC:
Core CABAC engine
Separate residual coding structure for transform block and transform skip block.
Context modeling for transform coefficients

The CABAC engine in HEVC uses a table-based probability transition process between 64 different representative probability states. In HEVC, the range ivlCurrRange representing the state of the coding engine is quantized to a set of 4 values prior to the calculation of the new interval range. The HEVC state transition can be implemented using a table containing all 64×4 8-bit pre-computed to values approximate the values of ivlCurrRange*pLPS (pStateIdx), where pLPS is the probability of the least probable symbol (LPS) and pStateIdx is the index of the current state. Also, a decode decision can be implemented using the pre-computed LUT. First ivILpsRange is obtained using the LUT as shown in Equation (3-47) below. Then, ivILpsRange is used to update ivlCurrRange and calculate the output binVal.

$$ivlLpsRange = rangeTabLps [ pStateIdx ] [ qRangeIdx ] \qquad ( 3 - 47 )$$

In VVC, the probability is linearly expressed by the probability index pStateIdx. Therefore, all the calculation can be done with equations without LUT operation. To improve the accuracy of probability estimation, a multi-hypothesis probability update model is applied. The pStateIdx used in the interval subdivision in the binary arithmetic coder is a combination of two probabilities pStateIdx0 and pStateIdx1. Two probabilities are associated with each context model and are updated independently with different adaptation rates. The adaptation rates of pStateIdx0 and pStateIdx1 for each context model are pre-trained based on the statistics of the associated bins. The probability estimate pStateIdx is the average of the estimates from the two hypotheses.

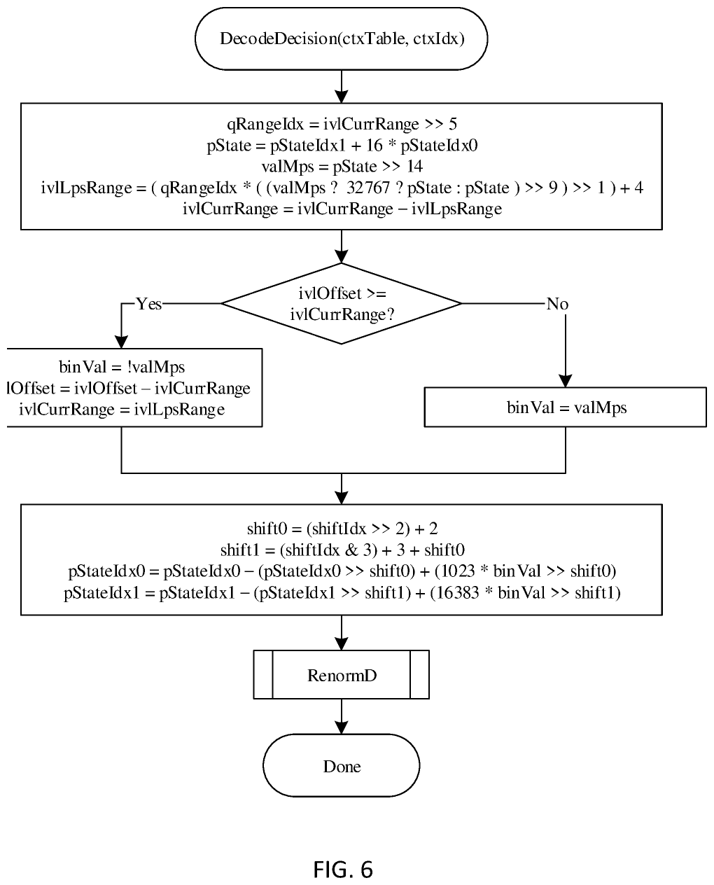

FIG. 6 shows an example of a flowchart for decoding a single binary decision in VVC.

As done in HEVC, VVC CABAC also has a QP dependent initialization process invoked at the beginning of each slice. Given the initial value of luma QP for the slice, the initial probability state of a context model, denoted as preCtxState, is derived as follows

$$m = slopeIdx \times 5 - 45 \qquad ( 3 - 48 )$$

$$n = ( offsetIdx ≪ 3 ) + 7 \qquad ( 3 - 49 )$$

$$preCtxState = Clip 3 ( 1 , 127 , ( ( m \times QP - 32 ) ) ≫ 4 ) + n ) \qquad ( 3 - 50 )$$

where slopeIdx and offsetIdx which are function of context number and slice type can be stored in 3 bits each, and total initialization values are represented by 6-bit precision. The probability state preCtxState represents the probability in the linear domain directly. Hence, preCtxState only needs proper shifting operations before input to arithmetic coding engine, and the logarithmic to linear domain mapping as well as the 256-byte table is saved. The two probabilities are then initialized as follows:

$$pStateIdx 0 = preCtxState ≪ 3 \qquad ( 3 - 51 )$$

$$pStateIdx 1 = preCtxState ≪ 7 \qquad ( 3 - 52 )$$

### Extended Precision

The intermediate precision used in the arithmetic coding engine is increased, including three elements. First, the precisions for two probability states are both increased to 15 bits, in comparison to 10 bits and 14 bits in VVC. Second, the LPS range update process is modified as below:

$$if q >= 16384 , q = {2}^{15} - 1 - q$$

$${R}_{LPS} = ( ( range * ( q ≫ 6 ) ) ≫ 9 ) + 1 ,$$

where range is a 9-bit variable representing the width of the current interval, q is a 15-bit variable representing the probability state of the current context model, and R_{LPS} is the updated range for LPS. This operation can also be realized by looking up a 512×256-entry in 9-bit look-up table. Third, at the encoder side, the 256-entry look-up table used for bits estimation in VTM is extended to 512 entries.

### Slice-Type-Based Window Size

Since statistics are different with different slice types, it is beneficial to have a context probability state updated at a rate that is optimal under the given slice type. Therefore, for each context model, three window sizes are pre-defined: one for each I-, B-, and P-slice types, respectively, as the initialization parameters.

The context initialization parameters and window sizes are retrained.

### Adaptive Update Rates, Weighted Average and State Carry-Over

While the update rules for the two probability states pStateIdx0 and pStateIdx1 stay the same, encoding of the n-th bit of a context is performed using probability states pStateIdx0′ and pStateIdx1′, which are obtained from pStateIdx0 and pStateIdx1 using window sizes which depend on the (n−1)-th bin:

$$pStateIdx {0}^{′} ( n ) = ( 1 - w {0}^{′} ( {b}_{n - 1} ) ) * pStateIdx 0 ( n - 1 ) + w {0}^{′} ( {b}_{n - 1} ) * {b}_{n - 1} \qquad ( 3 - 53 )$$

$$pStateIdx {1}^{′} ( n ) = ( 1 - w {1}^{′} ( {b}_{n - 1} ) ) * pStateIdx 1 ( n - 1 ) + w {1}^{′} ( {b}_{n - 1} ) * {b}_{n - 1} \qquad ( 3 - 54 )$$

The probability state used for coding can be a weighted average of pStateIdx0′ and pStateIdx1′ (instead of a simple average as before):

$$pStateIdx = alpha * pStateIdx {0}^{′} + ( 1 - alpha ) * pStateIdx {1}^{′} , \qquad ( 3 - 55 )$$

where the parameter alpha is obtained from a LUT and depends on the context and on the slice type.

The initial state of some B or P-slices can be inherited from previous slices instead of being re-initialized at each slice: more precisely, the two final states of each B-slice (or P-slice) are stored and used to initialize the next B-slice (or P-slice) in the same intra-period sharing the same temporal level and qp.

Thus, in the method above, the probabilities of the CABAC states that have been updated after the coding of the bin for a B or P-slice are stored and used for initialization of the CABAC probabilities for the coding the bin of a next B or P-slice.

Some embodiments presented herein relate to estimation of initial values of some parameters of a context-based arithmetic coder, such as a CABAC. In the embodiments presented herein, initial values of the parameters associated to a context are estimated dynamically to improve coding efficiency.

It is thus provided herein methods and apparatuses that estimate the initial values of a context's parameters that allows to provide better efficiency when entropy coding the bins of a frame, which bins are associated to the context. For instance, such parameters can be any one of the following: probabilities p0 and p1 associated to a context, update windows sizes w0 and w1 used for updating the probabilities of the context, as well as the weight alpha in equation (3-55).

Methods are described herein for determining initial values of the parameters of a context associated to bins to entropy encode/decode. In an image or video coder, the methods can be used for one or more context defined by the entropy coder. In any one of embodiments described herein, the entropy coder can be an arithmetic coder, such as a CABAC coder.

It should be understood that the wording initial values refers to the values used for initializing the parameters of the context adaptive entropy coder, such as a CABAC coder, the current value of some of these parameters may then evolve over time when encoding/decoding binary symbols, such as the updating of the probabilities of the context after encoding/decoding of a binary symbol.

In the present disclosure, the wording “parameter” refers to the parameter associated with a context of a context adaptive entropy coder, such as a CABAC coder or any other entropy coder operating using adaptive context. In the present disclosure, parameter or CABAC parameter or context parameter can be used interchangeably. In the present disclosure, context or model, CABAC context or CABAC model can be used interchangeably.

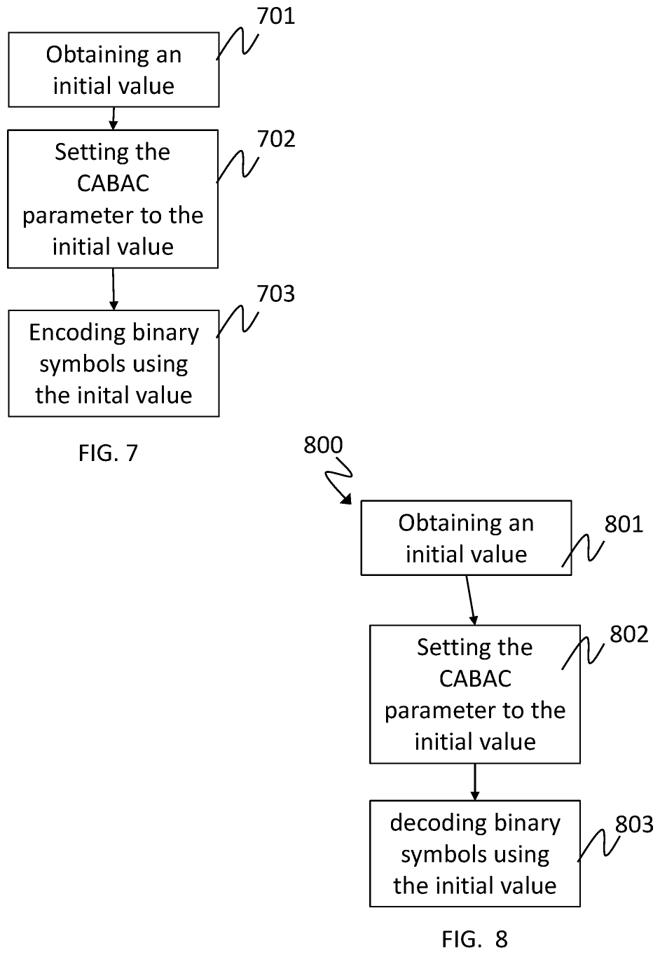

FIG. 7 illustrates an example of a method 700 for encoding an image or a video according to an embodiment. A sequence of binary symbols (bins) is obtained from the encoding modules (for instance the encoding modules of FIG. 2) processing a slice of an image or video to encode. The sequence of bins is for instance the symbols that are input to the entropy coding module 245, with non-binary symbols being binarized. The sequence of binary symbols is thus representative of an image or a video being encoded.

The embodiments are described herein in the case of a context associated with a sequence of bins to encode, the embodiments can apply to any one of the contexts used by the arithmetic encoder, and to one or more of its parameters.

At 701, an initial value is obtained for at least one parameter of the considered context of the entropy coder. The initial value is obtained based on video data. Some variants described further below are provided for determining the initial value. In a variant, the initial value is obtained based on a bitrate determination for entropy coding a set of binary symbols associated to the context. The set of binary symbols can be binary symbols obtained from a previous slice as the considered slice or the same slice as the considered slice.

At 702, the at least one parameter is initialized with the initial value and at 703, the at least one binary symbol is entropy coded using the at least one parameter initialized with the initial value.

FIG. 8 illustrates an example of a method 800 for decoding an image or a video according to an embodiment. A sequence of bins (binary symbols) to decode is obtained, for instance as the input of entropy decoding module 330 of FIG. 3. The sequence of binary symbols is representative of an image or a video to decode.

At 801, an initial value is obtained for at least one parameter of a considered context of the entropy decoder. The initial value is obtained based on video data. Some variants described further below are provided for obtaining the initial value at the decoder. In a variant, the initial value can be determined at the decoder in a same manner as in the encoder. In another variant, an information representative of the initial value is decoded from the video data. At 802, the at least one parameter is initialized with the initial value and at 803, the at least one binary symbol is entropy decoded using the at least one parameter initialized with the initial value.

In a variant, the determination of the initial values of the parameters can be done both at the encoder and the decoder sides. In this variant, the initial values are determined based on a first set of binary symbols and used for encoding/decoding a second set of binary symbols. For instance, the first set of binary symbols are the bins generated when encoding a previous slice. In another variant, the first set of binary symbols is binary symbols of the same slice as the second set of binary symbols but previously encoded.

In these variants, the estimated optimal parameters are stored and used to initialize, for instance, the next B or P-slice (alternatively, the next frame of same type and/or same QP).

This variant can be implemented at the decoder side, to avoid transmitting the determined initial value used for encoding the second set of binary symbols. This variant determines a best model parameters in terms of bitrate (i.e. an entropy coding providing a lowest bitrate) during the decoding of a first set of bins in order to get alternate model parameters for further decoding of a second set of bins.

In another variant, the initial values of the parameters are determined on the encoder side and signaled to the decoder. In this other variant, at 801, information representative of the initial values for the parameters are decoded from the data accessed by the decoder for decoding the image or video, for instance a bitstream received by the decoder. In this other variant, at the encoder, the first set and the second set of binary symbols can be the same since the initial values that are determined at the encoder for initializing the entropy encoder are transmitted to the decoder. The information representative of the initial values can be the initial values themselves, or a difference between the determined initial values and default values known by the decoder. In another variant, a plurality of sets of initial values associated to the one or more contexts are available at the decoder, and the information representative of the initial values indicates which sets of initial values to use for entropy decoding the sequence of bins. The plurality of sets of initial values can be known to the decoder, for instance specified in the video standards, or sent with the video data.

In a further variant, a flag is transmitted by the encoder at the beginning of each slice to signal if parameters of the entropy coder should indeed be updated (i.e. initialized with the estimated initial values) or if default parameters are used at initialization.

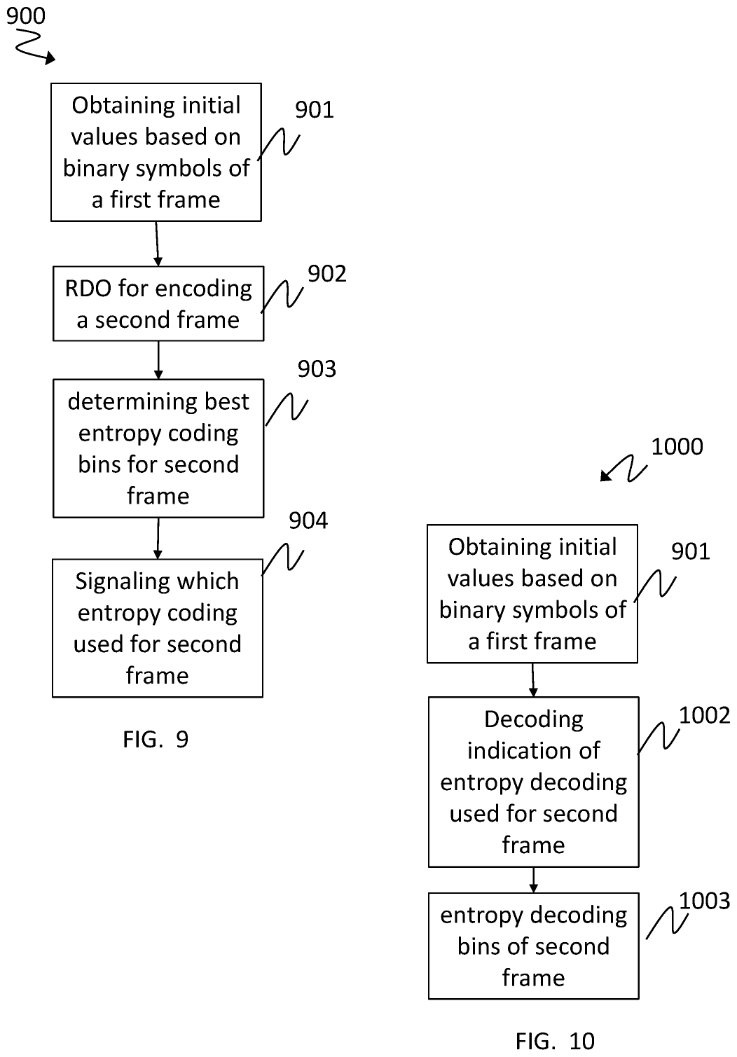

FIG. 9 illustrates a method 900 for encoding a sequence of binary symbols representative of image or video data, for at least one context of an entropy coder of a video encoder, according to an embodiment. At 901, at least one initial value is determined for at least one parameter of the context based on previously processed binary symbols. For instance, the previously processed binary symbols is a sequence of binary symbols associated to the same context that has been generated when encoding a frame or slice previous (first frame in FIG. 9) to the current frame (second frame in FIG. 9) or slice to encode. In this embodiment, a same mechanism for determining the initial values is done at the encoder and decoder. So, the initial values determined are not used here for encoding the bins of the previous frame or slice.

At 902, RDO (rate-distortion optimization) is performed for the current frame or slice. The current frame or slice can have a same type (I, B or P) as the previous frame or slice considered and/or a same QP. The RDO can be done using the default initial values of the context or the updated values determined at 901. RDO is performed for determining encoding decisions for the blocks of the current frame or slice. The current frame is then encoded by applying the encoding decisions taken by RDO for the blocks, providing the sequence of binary symbols representative of the residuals and syntax elements to entropy encode.

At 903, after encoding the current frame and before writing the bitstream, an entropy encoding of the binary symbols generated by the encoding of the current frame is performed using the updated values determined at 901. An entropy encoding of the binary symbols generated by the encoding of the current frame is also performed using the default values. The best entropy encoding (i.e. the entropy encoding providing the lowest bitrate) is selected. At 904, the entropy coded bins generated by the selected entropy encoding are written in the bitstream, as well as an indication (or a flag) to signal whether the updated values determined at 901 or the default values are used for encoding the bins of the current frame.

In a variant, several updated models are determined at 901 and stored. In this variant, several initial values for a same parameter can be determined. For instance, when initial values for several parameters of a same context are determined at 901, several sets of initial values for the parameters are available. The sets can be determined based on the first frame or on different frames. At 903, each available model is evaluated and the model providing the lowest bitrate is selected by the encoder, and signaled to the decoder, for instance by an index.

The mechanism described in reference with FIG. 9 can also be applicable to another variant in which initial values for the parameters are determined within a slice, not necessarily of type B or P, and used to update the parameters within the same slice; for example, the update can be done after a certain number of bins for the context have been observed, or once the norm of the estimated gradient reaches a certain threshold. The update can be performed only once per context, or periodically every N bins in the context (N being specified in the specification of the decoder for instance or signaled to the decoder), or every time the norm of the estimated gradient reaches a certain threshold (at which point the gradient is re-initialized to 0).

FIG. 10 illustrates a method 1000 for decoding a sequence of binary symbols representative of image or video data, for at least one context of an entropy coder of a video decoder, according to an embodiment. In this embodiment, a same mechanism for determining the initial values is done at the encoder and decoder. Therefore, step 901 of method 1000 is similar as the one performed for method 900. At 901, at least one initial value is determined for at least one parameter of the context based on a sequence of binary symbols associated to the same context obtained when decoding a previous frame or slice. At 1002, an indication is decoded that indicates whether the initial values obtained at 901 are to be used for entropy decoding the binary symbols of a current frame or whether default initial values are used, for instance, the values hard coded in the decoder or defined by the decoder standard specification. In a variant, step 1002 can be performed before step 901 at the decoder, so that the updates for the initial values are only determined at 901 if the decoded indication indicates so.

As with method 900, several sets of the updates for the initial values can be available at the decoder, and the decoded indication provides for selecting the set of updates to use for entropy decoding the binary symbols for the current frame. These available sets can be either determined at 901 under different configurations, or known by the decoder (e.g. defined by the decoder standard specification). At 1003, the binary symbols for the current frame are entropy decoded using the initial values indicated by the indication.

Some embodiments below further specify how to determine initial values for parameters for a current slice. These embodiments can all be applied to any of the parameters of the context based entropy coder: initial states probabilities, update windows, offset to update windows used at encoding time (see (3-53) and (3-54)), weight alpha (see (3-55)). These embodiments can be further adjusted by introducing criteria according to which the initial values are estimated, e.g., a gain in bitrate in the current frame has to be above a given value, and/or, at least a given number of bins for the parameters of the considered context have to be encoded.

### Complete Search

In an embodiment, determining the initial values is based on a complete search wherein estimates of the bitrate for all combinations of parameters can be computed exactly, and the best combination is then selected as the optimal one. This embodiment has the advantage of being optimal; however, the high number of combinations to be tested implies a huge computational overhead (both at encoder and at decoder side when the initial values are also determined at decoder).

A variant which greatly simplifies the estimation task is to restrict the search to a subset of values for the parameters. For example, for determining a window size, instead of testing all possible window sizes, only offsets of +1 or −1 with respect to the original window (default window known by the decoder) could be tested.

When initial values for several parameters have to be determined, another variant is to only consider the variation of one parameter at a time. For the previous example, if both windows w0 and w1 can have offsets of +1 or −1, instead of considering all the 9 possible combinations, only one window at a time is changed, resulting in 5 configurations to test.

### Gradient-Based Embodiment

In another embodiment, the initial values for the parameters are determined via a method of gradient descent type: considering the sequence of observed bins as a constant, the bitrate can be expressed as a function F of the context parameters. Indeed, the bitrate for N bits can be approximated by the entropy lower bound,

$${\sum }_{n = 0}^{N - 1} - {log}_{2} ( {p}_{n} ( {b}_{n} ) ) ,$$

where the probability pₙ is the probability model used for encoding (see (3-55)) and pₙ(bₙ) denotes the probability assigned to the observed bin bₙ. Developing the above expression through equations (3-53), (3-54), and through the update rule described above, allows to express the bitrate as a function F of the parameters (initial states, update windows, and weight alpha). One can then compute the gradient of F with respect to the different parameters: this is usually obtained recursively while the bins are entropy coded. The initial values are adjusted based on the gradient. For instance, in the same spirit as gradient descent, taking a step in the opposite direction as the gradient should lower the bitrate.

In a variant, the step taken is proportional to the gradient: if x denotes the vector of parameters, then the corrected parameters are

$${x}^{′} = x - a * ∇ F ,$$

where ∇F denotes the gradient (i.e., the vector of partial derivatives) of F with respect to the parameters x and a is a fixed positive number.

In another variant, each parameter is changed by a fixed amount only if the absolute value of the partial derivative of F with respect to such parameter is greater than a certain value. Both variants can be further generalized by taking more than just one step in the direction opposite to the gradient: in this case the gradient is re-evaluated before taking each step.

### Signaling

As in the previous section, it is proposed to determine better context parameters in order to obtain a better encoding efficiency than when using default initial values of the parameters. However, in this variant, the initial values for the parameters to be used are only determined at encoder side, for example using any one of the embodiments described above. The encoder then signals the determined initial values to the decoder, so that both agree on the parameters used to encode the bins in each context. The initial values can be signaled as correction of the default initial values, for example by signaling a difference between the determined initial values and the default initial values already known by the decoder.

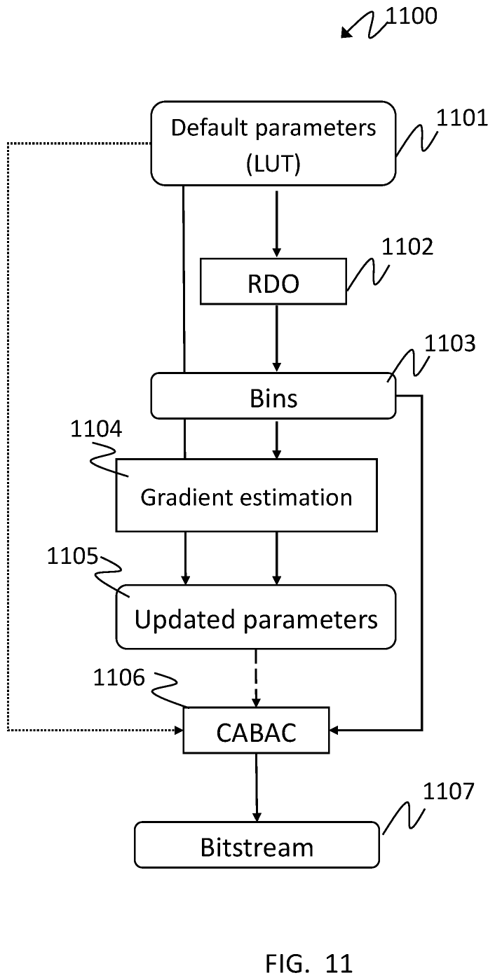

FIG. 11 illustrates an example of a method 1100 for encoding a sequence of binary symbols representative of image or video data, for at least one context of an entropy coder video encoder, according to an embodiment. At 1102, RDO (rate-distortion optimization) is performed for encoding a frame/slice. In this embodiment, the RDO is done using the default initial values of the context which can be obtained from a LUT at 1101. These default initial values are for example the ones defined by a video standard specification or the values known between the encoder and the decoder. The RDO generates a sequence of binary symbols at 1103. At 1104, optimized initial values for the entropy coder are determined based for instance on any one of the embodiments described above (complete search, gradient estimation). At 1105, it is determined whether the initial values determined at 1104 provides a lower bitrate than when using the default initial values, the initial values providing the lowest bitrate are selected. At 1106, the initial values selected at 1105 (default initial values illustrated with dotted lines or updated initial values illustrated with long dashed lines on FIG. 11) are used for entropy encoding the bins generated at 1103 to produce bitstream (1107). An indication signaling whether the initial values determined at 1104 are used for entropy encoding the bins of the current frame is also signaled in the bitstream. If the initial values determined at 1104 are used for entropy encoding the bins, then information representative of the initial values is also signaled in the bitstream.

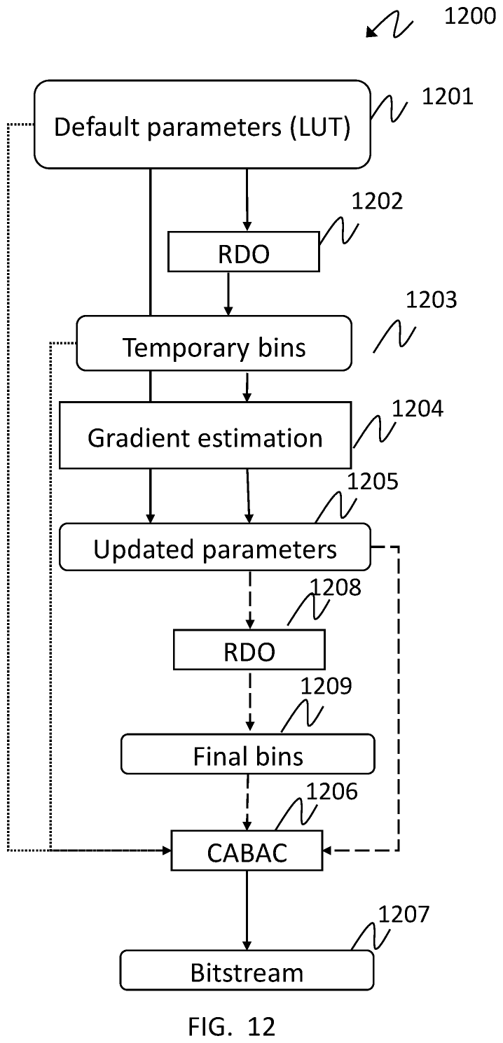

FIG. 12 illustrates an example of a method 1200 for encoding a sequence of binary symbols representative of image or video data, for at least one context of an entropy coder of a video encoder, according to another embodiment. This variant is a multi-pass variant wherein the updated parameters (initial values determined for the frame) are used by the encoder to perform RDO so that the bitstream is further optimized. At 1202, in a first pass, the RDO is done using the default initial values of the context which can be obtained from a LUT at 1201. The first RDO pass generates a sequence of binary symbols at 1203. At 1204, optimized initial values for the entropy coder are determined based for instance on any one of the embodiments described above (complete search, gradient estimation). At 1205, it is determined whether the initial values determined at 1204 provides a lower bitrate than when using the default initial values, the initial values providing the lowest bitrate are selected.

If the selected initial values are the ones determined at 1204 (path illustrated with long dashed lines on FIG. 12), a second RDO pass is done at 1208 using the initial values determined at 1204. The second RDO pass generates a new sequence of binary symbols at 1209. At 1206, the selected initial values are used for entropy encoding the bins generated at 1209 to produce a bitstream (1207).

At 1205, if the initial values selected are the default ones (path illustrated with dotted lines on FIG. 12), then at 1206, the default initial values are used for entropy encoding the bins generated at 1203 to produce the bitstream (1207).

An indication signaling whether the initial values determined at 1204 are used for entropy encoding the bins of the current frame is also signaled in the bitstream. If the initial values determined at 1204 are used for entropy encoding the bins, then information representative of the initial values is also signaled in the bitstream.

FIGS. 16 to 19 provide further embodiments for encoding and decoding a sequence of binary symbols representative of image or video data and more particularly wherein corrected initial values are carried over to the decoder. In the following, embodiments are described for CABAC context/model parameters, but the described embodiments can apply to any entropy coder based on context adaptative coding.

FIG. 16A illustrates a method for encoding an image or video according to an embodiment, and a corresponding method for decoding the image or video, wherein corrected initial values (or corrected parameters) determined for CABAC context/model parameters for a current frame are carried over to a future/next frame to be encoded or decoded. When the corrected initial values are provided to a future frame, these values can then be used during RDO of the future frame.

FIG. 16A comprises an encoder block 1610 depicting RDO performed for a current frame and providing as output a sequence of binary symbols representing the encoding decisions (1615) for the blocks of the current frame decided by the RDO. Classically, the RDO selects (1611) a best coding mode for each block of the current frame in terms of rate/distortion. During RDO for each block, the RDO generates a sequence of binary symbols which represents the values provided by the encoding choice (1611) and a CABAC context is selected (1612) for each bin of the sequence to encode the bin, the sequence of the bins is entropy coded (1613), providing a bitrate (1614) for the block. The block is reconstructed depending on the encoding choice and the distortion is evaluated. The encoding choice providing the best Rate/distortion trade-off is selected as the best coding mode for the block. The process is iterated for each block of the current frame. In some variants, RDO for the blocks can be done jointly, i.e. optimizing encoding choices for several blocks jointly.

In the RDO block (1610), the CABAC models used in entropy coding (1613) are initialized using default initial values, for instance, for a first frame in the video, default initial values are initial values that are known both at the encoder and decoder. For subsequent frames, default initial values are updated (1628) with the initial values determined for the current frame in the RDO entropy coding (1620) done for the current frame.

FIG. 16A also illustrates an encoder block 1620 which depicts the RDO entropy coding for encoding the sequence of bins representing the encoding decisions (1615) for each block of the current frame. The RDO entropy coding searches for one or more parameters of one or more CABAC models a new initial value that lowers the bitrate of the sequence of bins using this CABAC model. The new initial value can be obtained using an offset i from a default initial value, for instance the default initial value is the one that is used during the RDO (1610). Different new initial values can be evaluated for each parameter of a CABAC model to optimize.

For that, the RDO entropy coding performs a loop on different offsets for a current parameter to optimize. A best offset for a current parameter is for instance initialized to 0. For each offset (1621), the CABAC model is initialized (1622) with the corresponding new initial value, then the bins using that CABAC model are entropy coded (1623), and it is checked whether the offset provides a lower bitrate for the bins or not (1624). If this is the case, the offset is stored as a best offset. Another offset is then evaluated for the current parameter if available, otherwise, the RDO entropy coding passes to another parameter to optimize for the CABAC model or to another CABAC model to optimize, until all parameters for each CABAC model have been evaluated. In some variants, only a subset of CABAC models is optimized. In other variants, the offsets to be evaluated are in a given range.

The best offset for the parameters of the CABAC model are retrieved (1625) and the sequence of bins of the encoding decisions (1615) are entropy coded (1626) using CABAC models that are initialized with the new initial values obtained from the best offsets determined for the parameters to provide a bitstream representative of the image or video (1627). Information representative of the best offsets is also encoded in the bitstream (1627).

In this embodiment, the new initial values obtained from the best offsets are also used for initializing the CABAC models (1628) for a next frame. Thus, the new initial values are used in the RDO (1610) of the next frame, and these new initial values become the defaults initial values for the next frame.

FIG. 16A also comprises a decoder block 1630 depicting the decoding process of the bitstream. The best offsets are decoded from the bitstream (1631) to obtain the new initial values for the CABAC models. The CABAC models are initialized (1632) with the new initial values obtained and the sequence of bins for the current frame is entropy decoded (1633) to obtain the values representative of the coding of the blocks. The blocks of the current frame are then decoded and reconstructed (1634) to provide as output a reconstructed current frame. The new initial values obtained from the decoded offsets are also used for updating (1635) the CABAC models for a next frame. As an offset represents a correction from a default initial value for a parameter of a CABAC model, the default initial value for the next frame has to be updated with the new initial value of the current frame so that the correct initial value is reconstructed for the next frame with the offset signaled for the next frame. This update is done in a same manner as the update done on the encoder side (1628).

In a variant, when the corrected initial values determined for a current frame are provided for a future frame, constraints can be set to carry over the corrected initial values to a next frame. For instance, a constraint based on the temporal Id of the frames can be set, wherein the temporal Id of a frame is an index of temporal level of the frame in a hierarchical temporal decomposition of the video frames to be encoded. In this variant, the corrected initial values determined for the current frame are provided to a future frame that has a same temporal Id or to a future frame that as a higher temporal Id than the current frame. In this variant, when the sequence of video frames is decomposed into hierarchical temporal layers, then initial values for updating each temporal level have to be stored so that CABAC models for a frame are initialized with the initial values corresponding to the frame's temporal level. This variant can also be implemented in any one of the embodiments described herein.

FIG. 16B illustrates a method 1600′ for encoding an image or video according to an embodiment, and a corresponding method for decoding the image or video, wherein updated values of parameters of CABAC models are carried over to a future/next frame to be encoded or decoded. In other words, the final CABAC states of the CABAC models obtained after the entropy coding of a current frame are used for updating the CABAC models for a next frame. In this embodiment, the best initial values for the CABAC parameters determined for entropy encoding a current frame in the RDO entropy coding (1620) are used for entropy coding the bins of the current frame and the final state of the entropy coding is used for updating the CABAC models used in the RDO for a next frame.

FIG. 16B comprises an encoder block 1610′ depicting RDO performed for a current frame and providing as output a sequence of binary symbols representing the encoding decisions (1615′) for the blocks of the current frame decided by the RDO. Blocks 1611′-1615′ in RDO block 1610′ are identical to blocks 1611 to 1615 depicted in RDO block 1610 of FIG. 16A.

FIG. 16B also illustrates an encoder block 1620′ which depicts the RDO entropy coding for encoding the sequence of bins representing the encoding decisions (1615′) for each block of the current frame. Blocks 1621′-1627′ in RDO block 1620′ are identical to blocks 1621 to 1627 depicted in RDO block 1620 of FIG. 16A.

After the values of the current frame have been entropy coded (1626′) using CABAC models that have been initialized with the best initial values (1625′), the final CABAC state of the CABAC models is used for updating (1628′) the CABAC models for the RDO for a next frame.

That is, the parameters of the CABAC models in the RDO (1612′) are initialized with the corresponding values of the final state of the CABAC models after entropy coding of the current frame (1626′).

FIG. 16B also comprises a decoder block 1630′ depicting the decoding process of the bitstream. The best offsets are decoded from the bitstream (1631′) to obtain the new initial values for the CABAC models. The CABAC models are initialized (1632′) with the new initial values obtained and the sequence of bins for the current frame is entropy decoded (1633′) to obtain the values representative of the coding of the blocks. The blocks of the current frame are then decoded and reconstructed (1634′) to provide as output a reconstructed current frame. The final CABAC state of the entropy decoding is used for updating (1635′) the CABAC models for a next frame, that is the parameters of the CABAC models for the next frame are initialized with the corresponding values of the final state of the CABAC models after entropy decoding of the current frame (1633′). As an offset represents a correction from a default initial value for a parameter of a CABAC model, the default initial value for the next frame has to be updated in a similar manner as what is done on the encoder side (1628′) so that the correct initial value is reconstructed for the next frame with the offset signaled for the next frame.

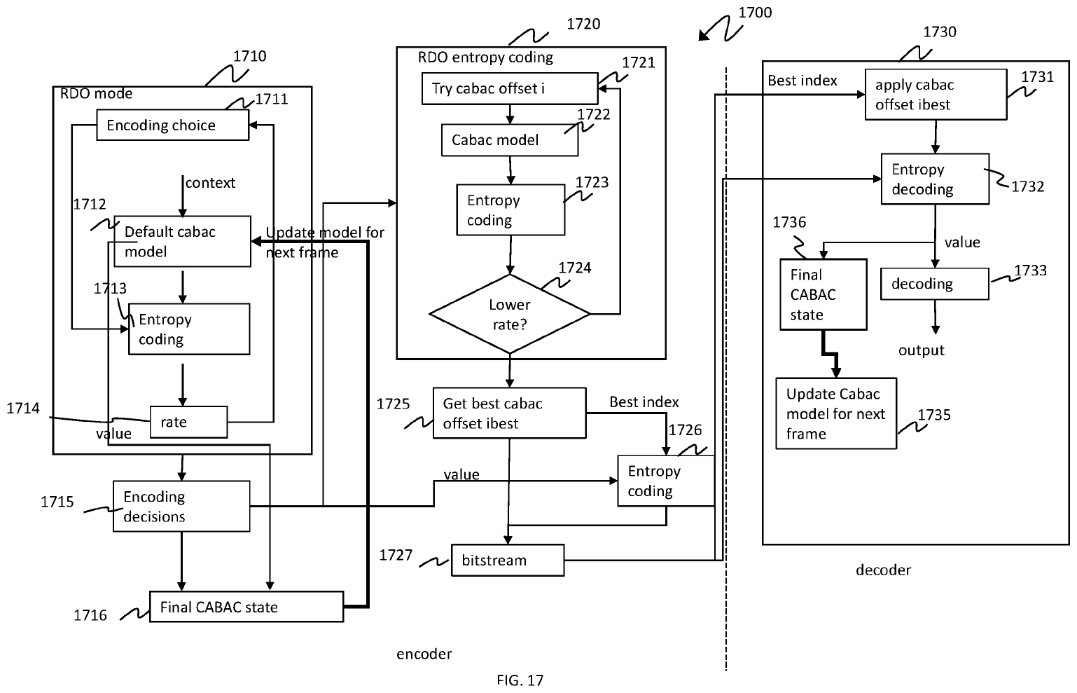

FIG. 17 illustrates a method 1700 for encoding an image or video according to an embodiment, and a corresponding method for decoding the image or video, wherein original CABAC parameters are carried over to a future/next frame to be encoded or decoded. In other words, in this embodiment, the final CABAC states of the CABAC models obtained after the RDO for a current frame are used for updating the CABAC models for a next frame, while optimized initial values are determined for the entropy coding of the current frame. Contrary to the embodiments of FIG. 16A or 16B, the best initial values for the CABAC parameters determined for entropy encoding a current frame are not used in the RDO for a next frame.

FIG. 17 comprises an encoder block 1710 depicting RDO performed for a current frame and providing as output a sequence of binary symbols representing the encoding decisions (1715) for the blocks of the current frame decided by the RDO. Blocks 1711-1715 in RDO block 1710 are identical to blocks 1611 to 1615 depicted in RDO block 1610 of FIG. 16A.

After the RDO is done for the current frame, the final CABAC states of the CABAC models is obtained (1716) for updating the CABAC models for the RDO for a next frame. The final CABAC state can be stored when performing the RDO or the values provided by the encoding decisions are entropy coded using the same CABAC models as the ones used in the RDO (1712). The final CABAC states correspond to the state of the parameters of the CABAC models after the sequence of bins generated for the current frame with the encoding decisions (1715) has been entropy coded using the default initial values for initializing the CABAC models.

In the RDO block 1710, the CABAC models used in entropy coding (1713) are initialized using default initial values, for instance, for a first frame, default initial values are the values known both at the encoder and decoder. For subsequent frames, default initial values are updated with the final CABAC state determined (1716) after RDO of a previous frame.

FIG. 17 also illustrates an encoder block 1720 which depicts the RDO entropy coding for encoding the sequence of bins representing the encoding decisions (1715) for each block of the current frame. In this embodiment, the best initial values for CABAC parameters are determined independently for each frame and the best initial values are not carried over to a next frame. Blocks 1721-1727 in RDO block 1720 are identical to blocks 1621 to 1627 depicted in RDO block 1620 of FIG. 16A.

FIG. 17 also comprises a decoder block 1730 depicting the decoding process of the bitstream. The best offsets are decoded from the bitstream to obtain the new initial values for initializing the CABAC models (1731). The sequence of bins for the current frame is entropy decoded (1732) to obtain the values representative of the coding of the blocks. The blocks of the current frame are then decoded and reconstructed (1733).

In the embodiment, the new initial values that are determined in the RDO entropy coding (1720) are encoded in the bitstream as offsets from default initial values that shall be known to the decoder, so that the decoder reconstruct the same initial values as the ones used on the encoder side. In this embodiment, the new initial values are obtained using offsets from the final CABAC state of the CABAC models of a previous frame obtained using default CABAC models used in the RDO (1716). Thus, the decoder block (1730) comprises a final state CABAC block (1736) that performs an entropy coding of the decoded values for the current frame provided by the entropy decoding (1732). This entropy coding (1736) uses the same default CABAC models as the ones used in the RDO encoder (1712) for the current frame. This allows to retrieve on the decoder side the final CABAC state that has been used on the encoder side to update the default CABAC models for the next frame (1735). In this way, the default CABAC models for the next frame are updated and the new initial values can be reconstructed for the next frame using the offsets decoded for the next frame.

The embodiments described above can be further modified so that, at a following frame, the encoder tests any one of the modifications of the default CABAC models described in the embodiments above with reference to FIG. 16A, 16B or 17. This can be achieved in an embodiment by storing in a database default CABAC models which are used as starting points to test possible modifications of the initial values of the starting points.

Depending on the variants, the database can comprise one default CABAC model at a time which is updated at each frame or periodically with initial values of CABAC models learned in the RDO entropy coding, with the CABAC state values either before or after the entropy coding of the current frame. In other variants, the database comprises more than one default CABAC models. CABAC models that are learned for one or more frames are added as default CABAC models to the database and signaling is sent to the decoder to indicate for a current frame which default CABAC models to use for reconstructing the initial values of the parameters of the CABAC models using the decoded offsets.

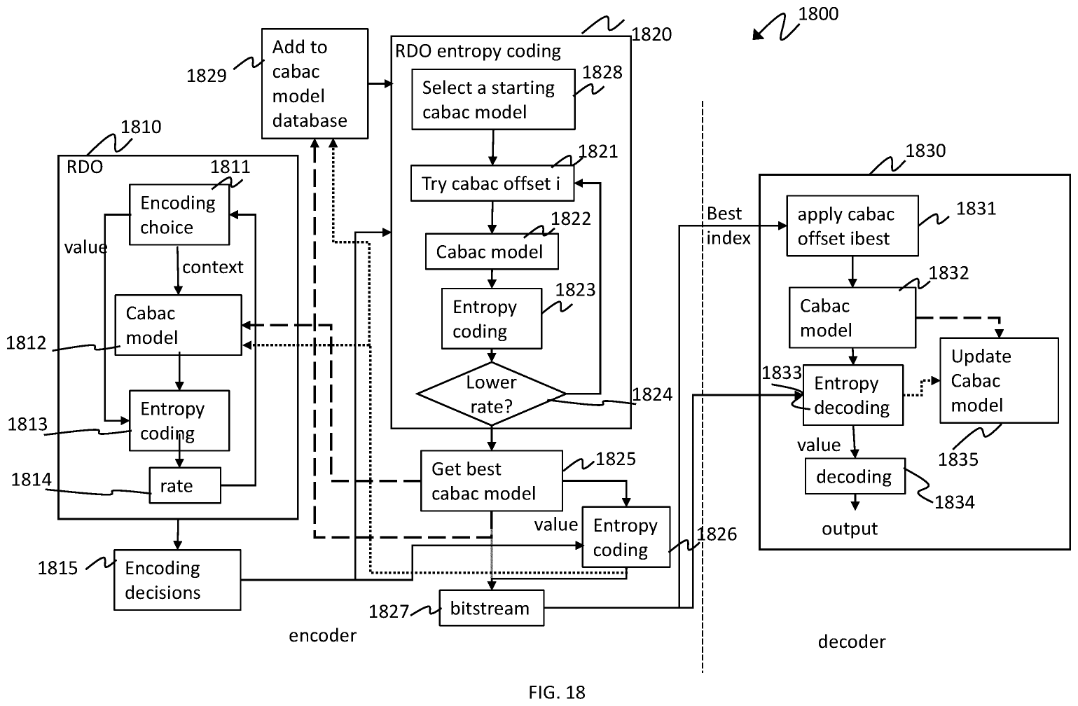

FIG. 18 illustrates a method 1800 for encoding an image or video according to this embodiment, and a corresponding method for decoding the image or video, wherein default CABAC models are stored in a database (1829) as starting points for the search of CABAC models for future/next frames to be encoded or decoded.

FIG. 18 comprises an encoder block 1810 depicting RDO performed for a current frame and providing as output a sequence of binary symbols representing the encoding decisions (1815) for the blocks of the current frame decided by the RDO. Blocks 1811-1815 in RDO block 1810 are identical to blocks 1611 to 1615 depicted in RDO block 1610 of FIG. 16A. Similarly to what is done in FIG. 16A or 16B, in the RDO, the default CABAC models used in entropy coding (1812) are initialized using default initial values, for instance, for a first frame, default initial values are values known both at the encoder and decoder. For subsequent, default initial values are updated with either the best initial values determined from a previous frame in the RDO entropy coding (long dashed arrow, 1825) done for the previous frame or the values of the final CABAC state of the entropy coding (dotted line arrow, 1826). The default initial values used in the RDO are added to the database (1829) as a new available starting model.

FIG. 18 also illustrates an encoder block 1820 which depicts the RDO entropy coding for encoding the sequence of bins representing the encoding decisions (1815) for each block of the current frame. In this embodiment, the best initial values for CABAC parameters are searched from a CABAC model starting point selected from the CABAC model database (1829). The CABAC model database comprises for one or more default CABAC models, one or more sets of CABAC parameters having given initial values. The CABAC model database is initially populated with the default CABAC models known both at the encoder and decoder. The CABAC model database is subsequently populated when other initial values for the parameters of the CABAC models are determined by the RDO entropy coding 1820.

During the RDO entropy coding, a default CABAC model is selected (1828) from the CABAC model database as a starting point for determining best initial values for the CABAC model. The best initial values are determined in a similar manner as in embodiments described with reference to FIG. 16A, 16B or 17. Blocks 1821-1827 in RDO block 1820 are identical to blocks 1621 to 1627 depicted in RDO block 1620 of FIG. 16A.

In this embodiment, the new initial values that are evaluated are obtained using offsets from the initial values of the CABAC model of the starting point selected (1828). The RDO entropy coding 1820 can be iterated for different CABAC models selected as starting points in the database (1829) and the starting point providing the lowest bitrate is selected. In this case, when several starting points are possible and the initial values are determined as offset from the values of the starting points, then an information representative of the starting point in the database is signaled in the bitstream (1827), so that the decoder knows which starting point to use.

FIG. 18 also comprises a decoder block 1830 depicting the decoding process of the bitstream. The best offsets are decoded from the bitstream to obtain the new initial values (1831) for initializing the CABAC models (1832). In case several starting points were available at the encoder, an information representative of the default CABAC model used as starting point is decoded and used to identify the CABAC models used as starting point for the current frame and to reconstruct the new initial values from the decoded offsets.

The sequence of bins for the current frame is entropy decoded (1833) to obtain the values representative of the coding of the blocks. The blocks of the current frame are then decoded and reconstructed (1834). Depending on the variant, the new initial values obtained (1831) (long dashed arrow) or the final CABAC state after entropy coding (dotted line arrow) are added to the database (1835) so as to be available as default CABAC model for the next frame (1835).

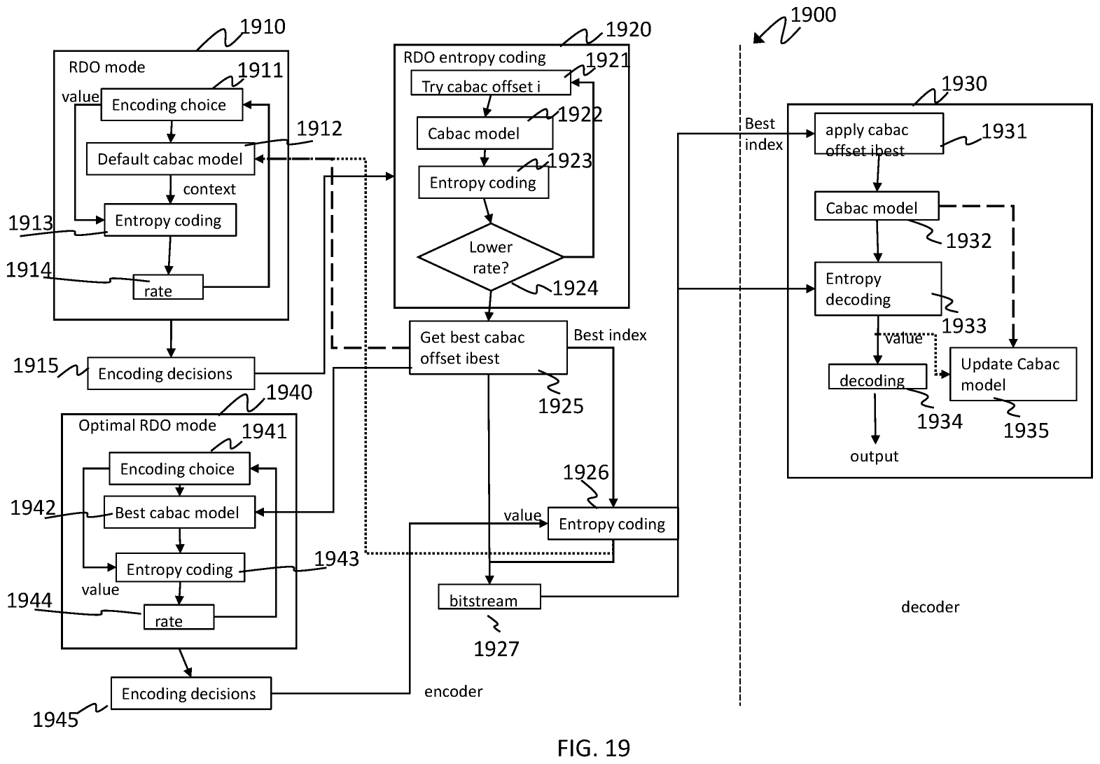

FIG. 19 illustrates a method 1900 for encoding an image or video according to an embodiment, and a corresponding method for decoding the image or video, wherein multi-pass RDO is performed and wherein the best initial values determined by the RDO entropy coding are used in a second RDO pass, so that the bitstream is further optimized and compression is improved. As for the other embodiments, FIG. 19 comprises an encoder RDO block 1910, an RDO entropy coding block 1920 and a decoder block 1930. These blocks 1910, 1920 and 1930 can be any one of the corresponding blocks from the other embodiments described in relation with FIG. 16A, 16B, 17, 18.

FIG. 19 also comprises an encoder block 1940 depicting a second RDO performed for the current frame and providing as output a sequence of binary symbols representing the encoding decisions (1945) for the blocks of the current frame decided by the second RDO. The second RDO performs similarly to the RDO block 1910 except that the CABAC models (1942) used in entropy coding (1943) are initialized using the best initial values determined (1925) by the RDO entropy coding block (1920).

The best offset for the parameters of the CABAC model are retrieved (1925) and the sequence of bins of the encoding decisions (1945) are entropy coded using the new initial values obtained from the best offsets for the parameters (1926) to provide a bitstream representative of the image or video (1927). Information representative of the best offsets is also encoded in the bitstream (1927).

Depending on the variants, the new initial values obtained from the best offsets can be used for initializing the CABAC models (long dashed line, 1912) for a next frame or the final CABAC state of the entropy coding can be used (dotted line, 1926).

On the decoder side (1930), the same update of the default CABAC models for the next frame shall be done.

In some embodiments described above, information representative of the determined initial values is signaled as corrections or offsets from the default initial values of the parameters of the CABAC models. Some variants are described below to signal the corrections/offsets of the parameters of the CABAC models. Any one of the variants described below can be applied to any or all of the CABAC parameters (update windows w0, w1, weight alpha, initial probability, shifted window w0′, W1′).

In a variant, the encoder signals a parameter correction for each CABAC context. In this variant, determining initial values for parameters can be done for all contexts of the entropy coder specified in a video coder. Given the high number of contexts (e.g. 571 CABAC contexts in the ECM-6.0 reference software), this generates a bitrate overhead which is often redundant as a lot of contexts are empty or are associated to very few bins.

In another embodiment, not all contexts are updated, and only a subset of the entropy coder contexts are updated. In this other variant, an indication providing for identifying the contexts that are to be updated is signaled in the bitstream. For example, the indexes of the contexts to be updated are signaled in the bitstream, for example at the beginning of each intra-period or at the beginning of each slice. In a variant, this can be done by establishing a ranking of most common contexts, for example an ordered list specifying these contexts can be hard-coded in the specification of the decoder. Then, it is signaled in the bitstream an indication signaling a number the contexts in the ordered list that should be updated.

In another variant, the indexes of the contexts to be updated are hard-coded in the specification of the decoder.

In another variant, multiple combinations of contexts can be available and an indication of a combination of contexts to be updated among the multiple combinations of contexts is signaled by the encoder.

In another embodiment global signaling is performed, that is only one signaling for all the updated CABAC models is transmitted.

In a variant of this embodiment, the signaling defines a parameter offset which is common to all CABAC contexts to update. For example, the signaling defines one same offset of +1 that applies to all update windows for all CABAC contexts. Thus, a single signal for the update windows of all CABAC contexts is transmitted.

In another variant, one signaling is used for all the CABAC contexts/models but the signaling is interpreted as a different offset for each context. This can be implemented through a look-up table (LUT) which is hard-coded in the spec. For example, the signaling of an offset +1 defines an offset of +1 for the first context, 0 for the second, −1 for the third and so on. The table below is an example where one of two possible global indexes is signaled to simultaneously correct the parameters of 6 CABAC contexts.

| Signaled | Ctx | Ctx | Ctx | Ctx | Ctx | Ctx |
|---|---|---|---|---|---|---|
| index | 0 | 1 | 2 | 3 | 4 | 5 |
| 0 | +1 | 0 | −1 | −1 | 0 | 0 |
| 1 | +1 | 0 | +2 | −1 | −2 | +1 |

In another embodiment, contexts are first divided into a given number of clusters: for example, the number of clusters and assignment of each context to a given cluster can be hard-coded in the spec, or signaled at the beginning of each intra-period or frame. Then the encoder transmits one signaling for each cluster.

In a variant, the signaling defines a parameter offset which is common to all CABAC contexts in the cluster. For example, the signaling defines an offset of +1 to all update windows for all CABAC contexts in the cluster.

In another variant, a same single signaling is interpreted as a different offset for each context in the cluster. This can be implemented through a look-up table (LUT) which is hard-coded in the spec. For example, the signaling defines an offset of +1 for the first context, 0 for the second, −1 for the third and so on.

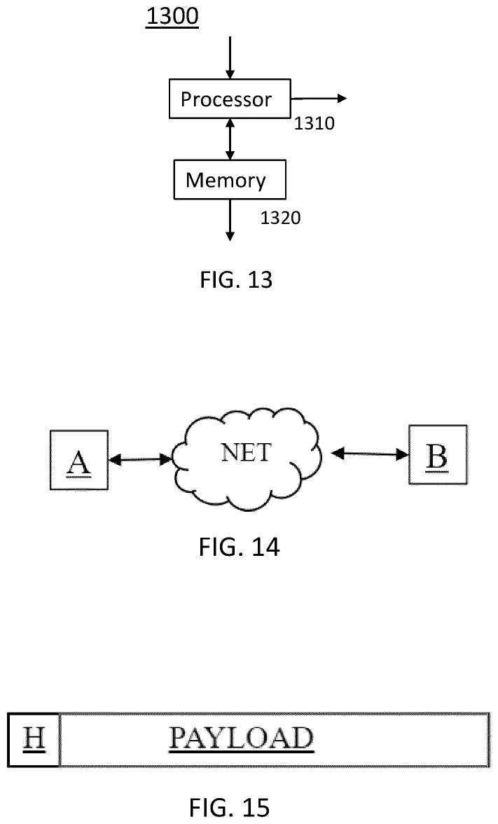

FIG. 13 illustrates a block diagram of a system within which aspects of the present embodiments may be implemented, according to another embodiment. FIG. 13 shows one embodiment of an apparatus 1300 for encoding or decoding an image or a video according to any one of the embodiments described herein. The apparatus comprises Processor 1310 and can be interconnected to a memory 1320 through at least one port. Both Processor 1310 and memory 1320 can also have one or more additional interconnections to external connections. Processor 1320 is also configured to obtain an initial value for at least one parameter of a context associated to at least one binary symbol of a sequence of binary symbols to arithmetically decode, wherein the initial value is obtained based on video data, initialize the at least one parameter to the initial value, and decode the sequence of binary symbols based on the at least one parameter initialized, using any one of the embodiments described herein. For instance, the processor 1321 is configured using a computer program product comprising code instructions that implements any one of embodiments described herein.

In another embodiment, processor 1320 is also configured to obtain an initial value for at least one parameter of a context associated to at least one binary symbol of a sequence of binary symbols to entropy encode, wherein the initial value is obtained based on video data, initialize the at least one parameter to the initial value, and encode the sequence of binary symbols based on the at least one parameter initialized, using any one of the embodiments described herein. For instance, the processor 1321 is configured using a computer program product comprising code instructions that implements any one of embodiments described herein.

In an embodiment, illustrated in FIG. 14, in a transmission context between two remote devices A and B over a communication network NET, the device A comprises a processor in relation with memory RAM and ROM which are configured to implement a method for encoding an image or a video, as described with FIGS. 1-13 and the device B comprises a processor in relation with memory RAM and ROM which are configured to implement a method for decoding an image or a video as described in relation with FIG. 1-13. In accordance with an example, the network is a broadcast network, adapted to broadcast/transmit encoded image or video from device A to decoding devices including the device B.

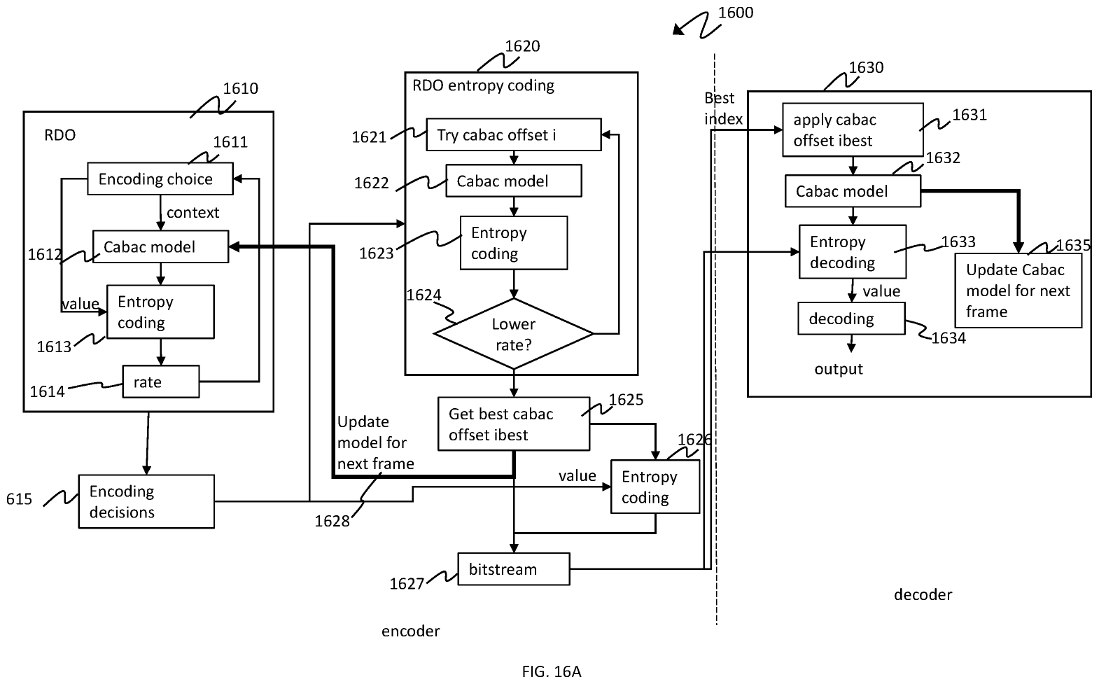

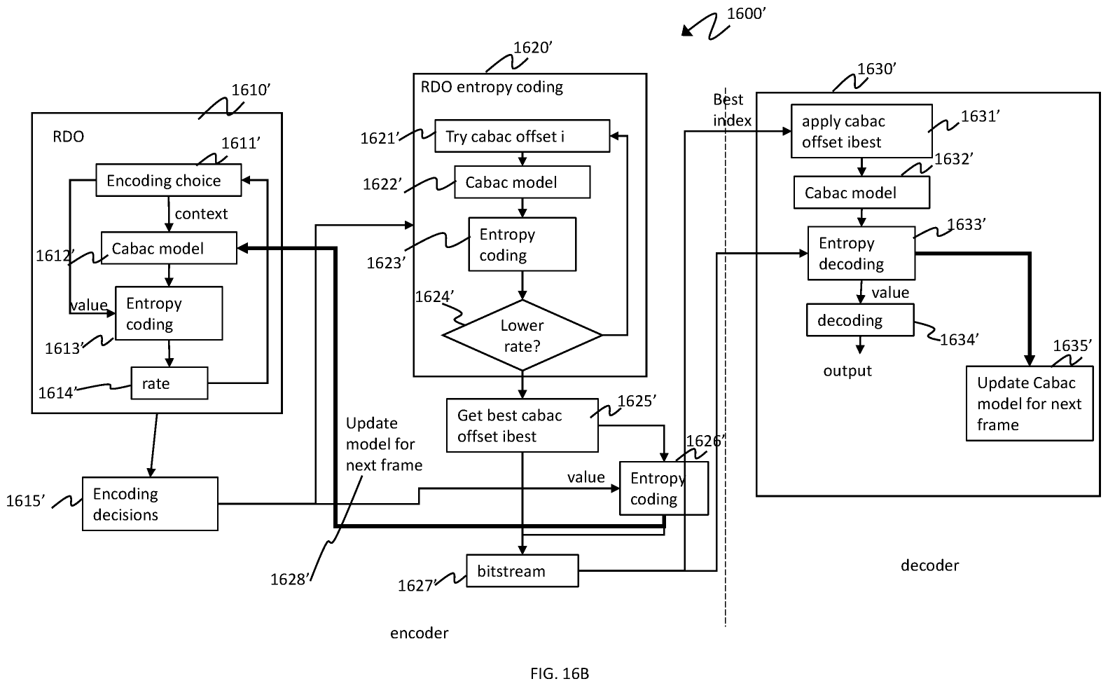

FIG. 15 shows an example of the syntax of a signal transmitted over a packet-based transmission protocol. Each transmitted packet P comprises a header H and a payload PAYLOAD. In some embodiments, the payload PAYLOAD may comprise image or video data according to any one of the embodiments described above. In a variant, the signal comprises data representative of any one of the following items:
An indication signaling whether at least one parameter of a context of the entropy coder associated to at least one binary symbol of a sequence of binary symbols is to be initialized with an initial value obtained from video data,
An information representative of at least one initial value of at least one parameter of a context of the entropy coder associated to at least one binary symbol of a sequence of binary symbols,
an indication indicating at least one context for which an initial value for at least one parameter of the at least one context is signaled.

Various implementations involve decoding. “Decoding”, as used in this application, can encompass all or part of the processes performed, for example, on a received encoded sequence in order to produce a final output suitable for display. In various embodiments, such processes include one or more of the processes typically performed by a decoder, for example, entropy decoding, inverse quantization, inverse transformation, and differential decoding. In various embodiments, such processes also, or alternatively, include processes performed by a decoder of various implementations described in this application, for example, entropy decoding a sequence of binary symbols to reconstruct image or video data.

As further examples, in one embodiment “decoding” refers only to entropy decoding, in another embodiment “decoding” refers only to differential decoding, and in another embodiment “decoding” refers to a combination of entropy decoding and differential decoding, and in another embodiment “decoding” refers to the whole reconstructing picture process including entropy decoding. Whether the phrase “decoding process” is intended to refer specifically to a subset of operations or generally to the broader decoding process will be clear based on the context of the specific descriptions and is believed to be well understood by those skilled in the art.

Various implementations involve encoding. In an analogous way to the above discussion about “decoding”, “encoding” as used in this application can encompass all or part of the processes performed, for example, on an input video sequence in order to produce an encoded bitstream. In various embodiments, such processes include one or more of the processes typically performed by an encoder, for example, partitioning, differential encoding, transformation, quantization, and entropy encoding. In various embodiments, such processes also, or alternatively, include processes performed by an encoder of various implementations described in this application, for example, determining re-sampling filter coefficients, re-sampling a decoded picture.

As further examples, in one embodiment “encoding” refers only to entropy encoding, in another embodiment “encoding” refers only to differential encoding, and in another embodiment “encoding” refers to a combination of differential encoding and entropy encoding.

Whether the phrase “encoding process” is intended to refer specifically to a subset of operations or generally to the broader encoding process will be clear based on the context of the specific descriptions and is believed to be well understood by those skilled in the art.

Note that the syntax elements as used herein, are descriptive terms. As such, they do not preclude the use of other syntax element names.

This disclosure has described various pieces of information, such as for example syntax, that can be transmitted or stored, for example. This information can be packaged or arranged in a variety of manners, including for example manners common in video standards such as putting the information into an SPS, a PPS, a NAL unit, a header (for example, a NAL unit header, or a slice header), or an SEI message. Other manners are also available, including for example manners common for system level or application level standards such as putting the information into one or more of the following:
a. SDP (session description protocol), a format for describing multimedia communication sessions for the purposes of session announcement and session invitation, for example as described in RFCs and used in conjunction with RTP (Real-time Transport Protocol) transmission.
b. DASH MPD (Media Presentation Description) Descriptors, for example as used in DASH and transmitted over HTTP, a Descriptor is associated to a Representation or collection of Representations to provide additional characteristic to the content Representation.
c. RTP header extensions, for example as used during RTP streaming.
d. ISO Base Media File Format, for example as used in OMAF and using boxes which are object-oriented building blocks defined by a unique type identifier and length also known as ‘atoms’ in some specifications.
e. HLS (HTTP live Streaming) manifest transmitted over HTTP. A manifest can be associated, for example, to a version or collection of versions of a content to provide characteristics of the version or collection of versions.

When a figure is presented as a flow diagram, it should be understood that it also provides a block diagram of a corresponding apparatus. Similarly, when a figure is presented as a block diagram, it should be understood that it also provides a flow diagram of a corresponding method/process.

Some embodiments refer to rate distortion optimization. In particular, during the encoding process, the balance or trade-off between the rate and distortion is usually considered, often given the constraints of computational complexity. The rate distortion optimization is usually formulated as minimizing a rate distortion function, which is a weighted sum of the rate and of the distortion. There are different approaches to solve the rate distortion optimization problem.

For example, the approaches may be based on an extensive testing of all encoding options, including all considered modes or coding parameters values, with a complete evaluation of their coding cost and related distortion of the reconstructed signal after coding and decoding. Faster approaches may also be used, to save encoding complexity, in particular with computation of an approximated distortion based on the prediction or the prediction residual signal, not the reconstructed one. Mix of these two approaches can also be used, such as by using an approximated distortion for only some of the possible encoding options, and a complete distortion for other encoding options. Other approaches only evaluate a subset of the possible encoding options. More generally, many approaches employ any of a variety of techniques to perform the optimization, but the optimization is not necessarily a complete evaluation of both the coding cost and related distortion.

The implementations and aspects described herein can be implemented in, for example, a method or a process, an apparatus, a software program, a data stream, or a signal. Even if only discussed in the context of a single form of implementation (for example, discussed only as a method), the implementation of features discussed can also be implemented in other forms (for example, an apparatus or program). An apparatus can be implemented in, for example, appropriate hardware, software, and firmware. The methods can be implemented in, for example, a processor, which refers to processing devices in general, including, for example, a computer, a microprocessor, an integrated circuit, or a programmable logic device.

Processors also include communication devices, such as, for example, computers, cell phones, portable/personal digital assistants (“PDAs”), and other devices that facilitate communication of information between end-users.

Reference to “one embodiment” or “an embodiment” or “one implementation” or “an implementation”, as well as other variations thereof, means that a particular feature, structure, characteristic, and so forth described in connection with the embodiment is included in at least one embodiment. Thus, the appearances of the phrase “in one embodiment” or “in an embodiment” or “in one implementation” or “in an implementation”, as well any other variations, appearing in various places throughout this application are not necessarily all referring to the same embodiment.

Additionally, this application may refer to “determining” various pieces of information. Determining the information can include one or more of, for example, estimating the information, calculating the information, predicting the information, or retrieving the information from memory.

Further, this application may refer to “accessing” various pieces of information. Accessing the information can include one or more of, for example, receiving the information, retrieving the information (for example, from memory), storing the information, moving the information, copying the information, calculating the information, determining the information, predicting the information, or estimating the information.

Additionally, this application may refer to “receiving” various pieces of information. Receiving is, as with “accessing”, intended to be a broad term. Receiving the information can include one or more of, for example, accessing the information, or retrieving the information (for example, from memory). Further, “receiving” is typically involved, in one way or another, during operations such as, for example, storing the information, processing the information, transmitting the information, moving the information, copying the information, erasing the information, calculating the information, determining the information, predicting the information, or estimating the information.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as is clear to one of ordinary skill in this and related arts, for as many items as are listed.

Also, as used herein, the word “signal” refers to, among other things, indicating something to a corresponding decoder. In this way, in an embodiment the same parameter is used at both the encoder side and the decoder side. Thus, for example, an encoder can transmit (explicit signaling) a particular parameter to the decoder so that the decoder can use the same particular parameter. Conversely, if the decoder already has the particular parameter as well as others, then signaling can be used without transmitting (implicit signaling) to simply allow the decoder to know and select the particular parameter. By avoiding transmission of any actual functions, a bit savings is realized in various embodiments. It is to be appreciated that signaling can be accomplished in a variety of ways. For example, one or more syntax elements, flags, and so forth are used to signal information to a corresponding decoder in various embodiments. While the preceding relates to the verb form of the word “signal”, the word “signal” can also be used herein as a noun.

As will be evident to one of ordinary skill in the art, implementations can produce a variety of signals formatted to carry information that can be, for example, stored or transmitted. The information can include, for example, instructions for performing a method, or data produced by one of the described implementations. For example, a signal can be formatted to carry the bitstream of a described embodiment. Such a signal can be formatted, for example, as an electromagnetic wave (for example, using a radio frequency portion of spectrum) or as a baseband signal. The formatting can include, for example, encoding a data stream and modulating a carrier with the encoded data stream. The information that the signal carries can be, for example, analog or digital information. The signal can be transmitted over a variety of different wired or wireless links, as is known. The signal can be stored on a processor-readable medium.

A number of embodiments has been described above. Features of these embodiments can be provided alone or in any combination, across various claim categories and types.

1. A method, comprising:
decoding an information for identifying at least one offset from a first initial value of at least one parameter of a context of an entropy coder, the at least one parameter comprising at least one of: a size of a window used for updating a probability value after decoding a binary symbol, or a weight used in a weighted average for determining a probability value for decoding a binary symbol,
the context being associated to at least one binary symbol of a sequence of binary symbols representative of an image or a video,
determining at least one second initial value of the at least one parameter using the at least one offset, and
entropy decoding the sequence of binary symbols using the at least one parameter initialized to the second initial value.

2. An apparatus, comprising one or more processors, wherein said one or more processors is operable to:
decode an information for identifying at least one offset from a first initial value of at least one parameter of a context of an entropy coder, the at least one parameter comprising at least one of: a size of a window used for updating a probability value after decoding a binary symbol, or a weight used in a weighted average for determining a probability value for decoding a binary symbol,
the context being associated to at least one binary symbol of a sequence of binary symbols representative of an image or a video,
determine at least one second initial value of the at least one parameter, using the at least one offset, and
entropy decode the sequence of binary symbols using the at least one parameter initialized to the second initial value.

3-4. (canceled)

5. A method, comprising:
obtaining a first initial value of at least one parameter of a context of an entropy coder, the at least one parameter comprising at least one of: a size of a window used for updating a probability value after encoding a binary symbol, or a weight used in a weighted average for determining a probability value for encoding a binary symbol, the context being associated to at least one binary symbol of a sequence of binary symbols representative of an image or a video,
determining a second initial value for the at least one, wherein determining the second initial value is based on a bitrate determination for entropy encoding a set of binary symbols associated to the context,
encoding an information for identifying at least one offset between the second initial value and the first initial value, and
entropy encoding the at least one binary symbol using the at least one parameter initialized to the second initial value.

6. An apparatus, comprising one or more processors, wherein said one or more processors is operable to:
obtain a first initial value of at least one parameter of a context of an entropy coder, the at least one parameter comprising at least one of: a size of a window used for updating a probability value after encoding a binary symbol, or a weight used in a weighted average for determining a probability value for encoding a binary symbol, the context being associated to at least one binary symbol of a sequence of binary symbols representative of an image or a video,
determine a second initial value for the at least one parameter, wherein determining the second initial value is based on a bitrate determination for entropy encoding a set of binary symbols associated to the context,
encode an information for identifying at least one offset between the second initial value and the first initial value, and
entropy encode the at least one binary symbol using the at least one parameter initialized to the second initial value.

7. (canceled)

8. The method of claim 1, wherein the information comprises an indication to indicate at least one context for which an offset for at least one parameter of the at least one context is signaled in image or video data.

9. The method of claim 8, wherein the indication is signaled for an intra-period or for a slice.

10. The method of claim 8, wherein an ordered list comprises one or more contexts, and wherein the indication indicates a number of contexts in the ordered list for which an offset is signaled in the image or video data.

11. The method of claim 8, wherein the indication indicates a given set of contexts among a plurality of sets of contexts, for which an offset is signaled in the image or video data.

12-19. (canceled)

20. The method of claim 1, wherein the information comprises an indication signaling whether an update for the first initial value of the at least one parameter of the context is determined or a default initial value is used.

21-22. (canceled)

23. The method of claim 20, wherein the default initial value is a value of the at least one parameter of a context stored in a context database.

24. The method of claim 23, wherein the information comprises an indication identifying the context stored in the context database.

25. (canceled)

26. A non-transitory computer readable medium storing executable program instructions to cause a computer executing the instructions to perform a method according to claim 1.

27. (canceled)

28. A non-transitory computer readable medium storing a bitstream comprising data representative of an image or a video encoded using the method of claim 3.

29. The apparatus according to claim 2, comprising:
at least one of (i) an antenna configured to receive a signal, the signal including data representative of an image or a video, (ii) a band limiter configured to limit the signal to a band of frequencies that includes the data representative of the image or video, or (iii) a display configured to display the image or video.

30. (canceled)

31. The apparatus of claim 2, wherein the information comprises an indication to indicate at least one context for which an offset for at least one parameter of the at least one context is signaled in image or video data.

32. The apparatus of claim 31, wherein the indication is signaled for an intra-period or for a slice.

33. The apparatus of claim 31, wherein an ordered list comprises one or more contexts, and wherein the indication indicates a number of contexts in the ordered list for which an offset is signaled in the image or video data.

34. The apparatus of claim 31, wherein the indication indicates a given set of contexts among a plurality of sets of contexts, for which an offset is signaled in the image or video data.

35. The apparatus of claim 2, wherein the information comprises an indication signaling whether an update for the first initial value of the at least one parameter of the context is determined or a default initial value is used.

36. The apparatus of claim 35, wherein the default initial value is a value of the at least one parameter of a context stored in a context database.
